(19) United States
(12) Patent Application Publication
(10) Pub. No.: US 2024/0147706 A1
(43) Pub. Date: May 2, 2024

(54) SEMICONDUCTOR MEMORY DEVICE

(71) Applicant: SAMSUNG ELECTRONICS CO., LTD., Suwon-si (KR)

(72) Inventors: Keunui KIM, Suwon-si (KR); Kiseok LEE, Suwon-si (KR); Eunsuk JANG, Suwon-si (KR); Seokhan PARK, Suwon-si (KR); Seok-Ho SHIN, Suwon-si (KR); Joongchan SHIN, Suwon-si (KR); Moonyoung JEONG, Suwon-si (KR)

(21) Appl. No.: 18/370,149

(22) Filed: Sep. 19, 2023

(30) Foreign Application Priority Data
Oct. 28, 2022 (KR) 10-2022-0140983

(51) Int. Cl. H10B 12/00

(52) U.S. Cl. CPC H10B 12/488; H10B 12/315; H10B 12/482; H10B 12/50

(57) ABSTRACT

A semiconductor memory device may include a substrate, a bit line extending in a first direction on the substrate, a first word line and a second word line extending in a second direction to cross the bit line, a back-gate electrode extending in the second direction between the first word line and the second word line, first and second active patterns disposed between the first and second word lines and the back-gate electrode and connected to the bit line, contact patterns coupled to the first and second active patterns, respectively, a first back-gate capping pattern between the contact patterns and the back-gate electrode, and first gate capping patterns between the contact patterns and the first and second word lines. The first back-gate capping pattern and the first gate capping pattern may have first and second seams, which are extended in the second direction and are located at different vertical levels.

### CROSS-REFERENCE TO RELATED APPLICATIONS

This U.S. non-provisional patent application claims priority under 35 U.S.C. § 119 to Korean Patent Application No. 10-2022-0140983, filed on Oct. 28, 2022, in the Korean Intellectual Property Office, the entire contents of which are hereby incorporated by reference.

### BACKGROUND

### 1. Field

Embodiments relate to a semiconductor memory device, and in particular, to a semiconductor memory device with improved electrical characteristics and an increased integration density.

### 2. Description of the Related Art

Higher integration of semiconductor devices is desirable to satisfy consumer demands for superior performance and inexpensive prices. In the case of semiconductor devices, since their integration is an important factor in determining product prices, increased integration is especially desired. In the case of two-dimensional or planar semiconductor devices, since their integration is mainly determined by the area occupied by a unit memory cell, integration is greatly influenced by the level of a fine pattern forming technology. However, the extremely expensive process equipment needed to increase pattern fineness may set a practical limitation on increasing integration for two-dimensional or planar semiconductor devices. Accordingly, various semiconductor technologies have been suggested to improve an integration density, resistance, and current driving ability of a semiconductor device.

### SUMMARY

An embodiment may provide a semiconductor memory device with improved electrical characteristics and an increased integration density.

According to an embodiment, a semiconductor memory device may include a substrate, a bit line disposed on the substrate and extending in a first direction, a first word line and a second word line extending in a second direction to cross the bit line, a back-gate electrode disposed between the first word line and the second word line and extending in the second direction, a first active pattern disposed between the first word line and the back-gate electrode and connected to the bit line, a second active pattern disposed between the second word line and the back-gate electrode and connected to the bit line, contact patterns coupled to the first and second active patterns, respectively, a first back-gate capping pattern between the contact patterns and a top surface of the back-gate electrode, and first gate capping patterns between the contact patterns and top surfaces of the first and second word lines. The first back-gate capping pattern may have a first seam that is formed therein and extend in the second direction. Each of the first gate capping patterns may have a second seam that is formed therein and extends in the second direction. The first seam and the second seam may be located at different vertical levels.

According to an embodiment, a semiconductor memory device may include a substrate, a bit line provided on the substrate and extending in a first direction, first and second active patterns alternately disposed in the first direction on the bit line, a back-gate electrode disposed between adjacent ones of the first and second active patterns and extending in a second direction to cross the bit line, first word lines disposed adjacent to first side surfaces of the first active patterns respectively and extending in the second direction, second word lines disposed adjacent to second side surfaces of the second active patterns respectively and extending in the second direction, contact patterns connected to the first and second active patterns, respectively, a first back-gate capping pattern between the contact patterns and the back-gate electrode, first gate capping patterns between the contact patterns and the first and second word lines, a second back-gate capping pattern between the bit line and the back-gate electrode, and second gate capping patterns between the bit line and the first and second word lines. The first back-gate capping pattern may have a first seam that is formed therein and is adjacent to the back-gate electrode, and each of the first gate capping patterns may have a second seam that is formed therein and is adjacent to the contact patterns. The first seam of the first back-gate capping pattern may be vertically spaced apart from the contact patterns, and the second seams of the first gate capping patterns may be vertically spaced apart from top surfaces of the first and second word lines.

According to an embodiment, a semiconductor memory device may include a substrate, bit lines disposed on the substrate and extending in a first direction, a shielding conductive pattern including line portions, which are disposed between adjacent ones of the bit lines and extend in the first direction, first and second active patterns alternately disposed in the first direction, on each of the bit lines, back-gate electrodes, which are respectively disposed between adjacent ones of the first and second active patterns and extend in a second direction to cross the bit lines, first word lines disposed adjacent to the first active patterns respectively and extending in the second direction, second word lines disposed adjacent to the second active patterns respectively and extending in the second direction, a first back-gate capping pattern between the contact patterns and the back-gate electrode, first gate capping patterns between the contact patterns and the first and second word lines, a second back-gate capping pattern between the bit lines and the back-gate electrode, second gate capping patterns between the bit lines and the first and second word lines, contact patterns coupled to the first and second active patterns, respectively, and data storage patterns coupled to the contact patterns, respectively. The first back-gate capping pattern may have a first seam, which is formed therein and is extended in the second direction, and each of the first gate capping patterns may have a second seam, which is formed therein and is extended in the second direction. The first seam may be adjacent to a top surface of the back-gate electrode, and the second seams may be adjacent to the contact patterns.

### BRIEF DESCRIPTION OF THE DRAWINGS

Features will become apparent to those of skill in the art by describing in detail exemplary embodiments with reference to the attached drawings in which:

FIG. 1 is a plan view illustrating a semiconductor memory device according to an embodiment.

FIG. 2A is a sectional view, which is taken along lines A-A′, B-B′, and C-C′ of FIG. 1 to illustrate a semiconductor memory device according to an embodiment.

FIG. 2B is a sectional view, which is taken along lines D-D′ and E-E′ of FIG. 1 to illustrate a semiconductor memory device according to an embodiment.

FIG. 2C is a sectional view, which is taken along lines F-F′, G-G′, and H-H′ of FIG. 1 to illustrate a semiconductor memory device according to an embodiment.

FIGS. 3A and 3B are enlarged sectional views illustrating a portion ‘P1’ of FIG. 2B.

FIG. 3C is an enlarged sectional view illustrating a portion ‘P2’ of FIG. 2B.

FIG. 4A is a sectional view, which is taken along the line D-D′ of FIG. 1 to illustrate a semiconductor memory device according to an embodiment.

FIG. 4B is an enlarged sectional view illustrating a portion ‘P3’ of FIG. 4A.

FIG. 5A is a sectional view, which is taken along the line D-D′ of FIG. 1 to illustrate a semiconductor memory device according to an embodiment.

FIG. 5B is an enlarged sectional view illustrating a portion ‘P4’ of FIG. 5A.

FIG. 6A is a sectional view, which is taken along lines A-A′, B-B′, and C-C′ of FIG. 1 to illustrate a semiconductor memory device according to an embodiment.

FIG. 6B is a sectional view, which is taken along lines D-D′ and E-E′ of FIG. 1 to illustrate a semiconductor memory device according to an embodiment.

FIG. 6C is a sectional view, which is taken along lines F-F′, G-G′, and H-H′ of FIG. 1 to illustrate a semiconductor memory device according to an embodiment.

FIG. 7A is a sectional view, which is taken along lines A-A′, B-B′, and C-C′ of FIG. 1 to illustrate a semiconductor memory device according to an embodiment.

FIG. 7B is a sectional view, which is taken along the line D-D′ and E-E′ of FIG. 1 to illustrate a semiconductor memory device according to an embodiment.

FIG. 7C is a sectional view, which is taken along lines F-F′, G-G′, and H-H′ of FIG. 1 to illustrate a semiconductor memory device according to an embodiment.

FIG. 8A is a sectional view, which is taken along lines A-A′, B-B′, and C-C′ of FIG. 1 to illustrate a semiconductor memory device according to an embodiment.

FIG. 8B is a sectional view, which is taken along the line D-D′ and E-E′ of FIG. 1 to illustrate a semiconductor memory device according to an embodiment.

FIG. 8C is a sectional view, which is taken along lines F-F′, G-G′, and H-H′ of FIG. 1 to illustrate a semiconductor memory device according to an embodiment.

FIG. 9A is a sectional view, which is taken along lines A-A′, B-B′, and C-C′ of FIG. 1 to illustrate a semiconductor memory device according to an embodiment.

FIG. 9B is a sectional view, which is taken along the line D-D′ and E-E′ of FIG. 1 to illustrate a semiconductor memory device according to an embodiment.

FIG. 9C is a sectional view, which is taken along lines F-F′, G-G′, and H-H′ of FIG. 1 to illustrate a semiconductor memory device according to an embodiment.

FIG. 10A is a sectional view, which is taken along lines A-A′, B-B′, and C-C′ of FIG. 1 to illustrate a semiconductor memory device according to an embodiment.

FIG. 10B is a sectional view, which is taken along the line D-D′ and E-E′ of FIG. 1 to illustrate a semiconductor memory device according to an embodiment.

FIG. 10C is a sectional view, which is taken along lines F-F′, G-G′, and H-H′ of FIG. 1 to illustrate a semiconductor memory device according to an embodiment.

FIG. 11A is a sectional view, which is taken along lines A-A′, B-B′, and C-C′ of FIG. 1 to illustrate a semiconductor memory device according to an embodiment.

FIG. 11B is a sectional view, which is taken along the line D-D′ and E-E′ of FIG. 1 to illustrate a semiconductor memory device according to an embodiment.

FIG. 11C is a sectional view, which is taken along lines F-F′, G-G′, and H-H′ of FIG. 1 to illustrate a semiconductor memory device according to an embodiment.

FIG. 12A is a sectional view, which is taken along lines A-A′, B-B′, and C-C′ of FIG. 1 to illustrate a semiconductor memory device according to an embodiment.

FIG. 12B is a sectional view, which is taken along the line D-D′ and E-E′ of FIG. 1 to illustrate a semiconductor memory device according to an embodiment.

FIG. 12C is a sectional view, which is taken along lines F-F′, G-G′, and H-H′ of FIG. 1 to illustrate a semiconductor memory device according to an embodiment.

FIG. 13A is a sectional view, which is taken along lines A-A′, B-B′, and C-C′ of FIG. 1 to illustrate a semiconductor memory device according to an embodiment.

FIG. 13B is a sectional view, which is taken along the line D-D′ and E-E′ of FIG. 1 to illustrate a semiconductor memory device according to an embodiment.

FIG. 13C is a sectional view, which is taken along lines F-F′, G-G′, and H-H′ of FIG. 1 to illustrate a semiconductor memory device according to an embodiment.

FIG. 14A is a sectional view, which is taken along lines A-A′, B-B′, and C-C′ of FIG. 1 to illustrate a semiconductor memory device according to an embodiment.

FIG. 14B is a sectional view, which is taken along the line D-D′ and E-E′ of FIG. 1 to illustrate a semiconductor memory device according to an embodiment.

FIG. 14C is a sectional view, which is taken along lines F-F′, G-G′, and H-H′ of FIG. 1 to illustrate a semiconductor memory device according to an embodiment.

FIG. 15A is a sectional view, which is taken along lines A-A′, B-B′, and C-C′ of FIG. 1 to illustrate a semiconductor memory device according to an embodiment.

FIG. 15B is a sectional view, which is taken along the line D-D′ and E-E′ of FIG. 1 to illustrate a semiconductor memory device according to an embodiment.

FIG. 15C is a sectional view, which is taken along lines F-F′, G-G′, and H-H′ of FIG. 1 to illustrate a semiconductor memory device according to an embodiment.

FIG. 16A is a sectional view, which is taken along lines A-A′, B-B′, and C-C′ of FIG. 1 to illustrate a semiconductor memory device according to an embodiment.

FIG. 16B is a sectional view, which is taken along the line D-D′ and E-E′ of FIG. 1 to illustrate a semiconductor memory device according to an embodiment.

FIG. 16C is a sectional view, which is taken along lines F-F′, G-G′, and H-H′ of FIG. 1 to illustrate a semiconductor memory device according to an embodiment.

FIG. 17A is a sectional view, which is taken along lines A-A′, B-B′, and C-C′ of FIG. 1 to illustrate a semiconductor memory device according to an embodiment.

FIG. 17B is a sectional view, which is taken along the line D-D′ and E-E′ of FIG. 1 to illustrate a semiconductor memory device according to an embodiment.

FIG. 17C is a sectional view, which is taken along lines F-F′, G-G′, and H-H′ of FIG. 1 to illustrate a semiconductor memory device according to an embodiment.

FIG. 18A is a sectional view, which is taken along lines A-A′, B-B′, and C-C′ of FIG. 1 to illustrate a semiconductor memory device according to an embodiment.

FIG. 18B is a sectional view, which is taken along the line D-D′ and E-E′ of FIG. 1 to illustrate a semiconductor memory device according to an embodiment.

FIG. 18C is a sectional view, which is taken along lines F-F′, G-G′, and H-H′ of FIG. 1 to illustrate a semiconductor memory device according to an embodiment.

FIG. 19A is a sectional view, which is taken along lines A-A′, B-B′, and C-C′ of FIG. 1 to illustrate a semiconductor memory device according to an embodiment.

FIG. 19B is a sectional view, which is taken along the line D-D′ and E-E′ of FIG. 1 to illustrate a semiconductor memory device according to an embodiment.

FIG. 19C is a sectional view, which is taken along lines F-F′, G-G′, and H-H′ of FIG. 1 to illustrate a semiconductor memory device according to an embodiment.

FIG. 20A is a sectional view, which is taken along lines A-A′, B-B′, and C-C′ of FIG. 1 to illustrate a semiconductor memory device according to an embodiment.

FIG. 20B is a sectional view, which is taken along the line D-D′ and E-E′ of FIG. 1 to illustrate a semiconductor memory device according to an embodiment.

FIG. 20C is a sectional view, which is taken along lines F-F′, G-G′, and H-H′ of FIG. 1 to illustrate a semiconductor memory device according to an embodiment.

FIG. 21A is a sectional view, which is taken along lines A-A′, B-B′, and C-C′ of FIG. 1 to illustrate a semiconductor memory device according to an embodiment.

FIG. 21B is a sectional view, which is taken along the line D-D′ and E-E′ of FIG. 1 to illustrate a semiconductor memory device according to an embodiment.

FIG. 21C is a sectional view, which is taken along lines F-F′, G-G′, and H-H′ of FIG. 1 to illustrate a semiconductor memory device according to an embodiment.

FIGS. 22A to 22I are sectional views, which are taken along the line D-D′ of FIG. 1 to illustrate a method of fabricating a semiconductor memory device according to an embodiment.

FIGS. 23A to 23I are sectional views, which are taken along the line D-D′ of FIG. 1 to illustrate a method of fabricating a semiconductor memory device according to an embodiment.

### DETAILED DESCRIPTION

Example embodiments will now be described more fully with reference to the accompanying drawings, in which example embodiments are shown.

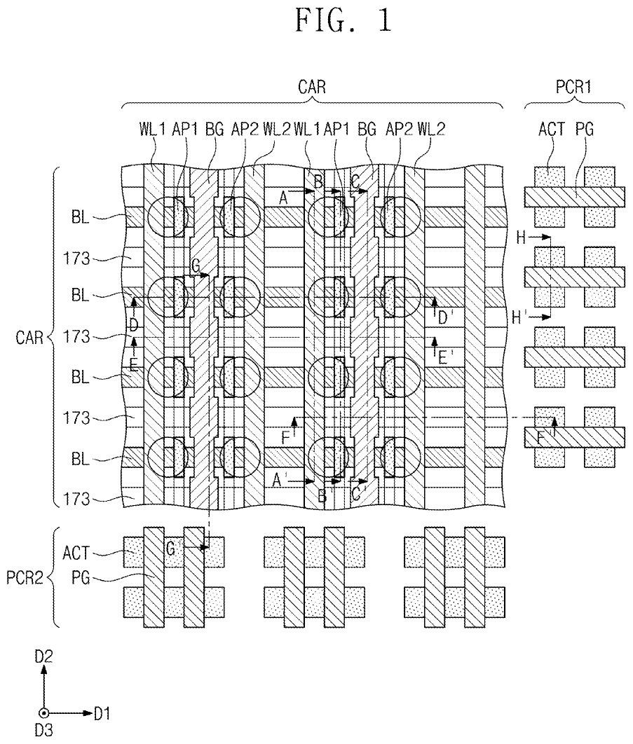

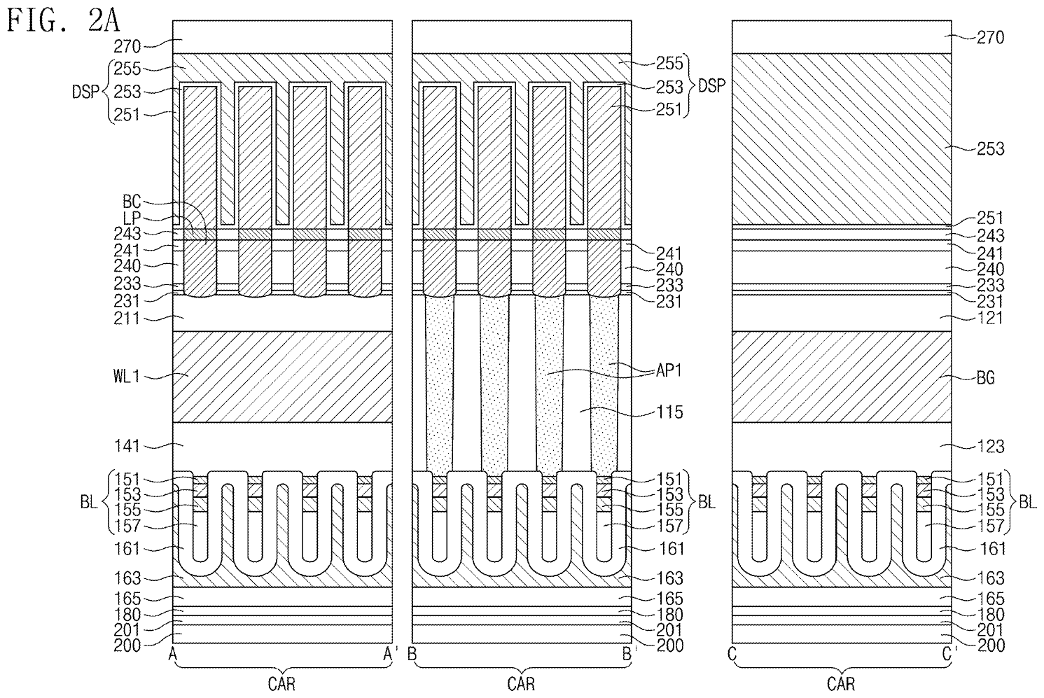

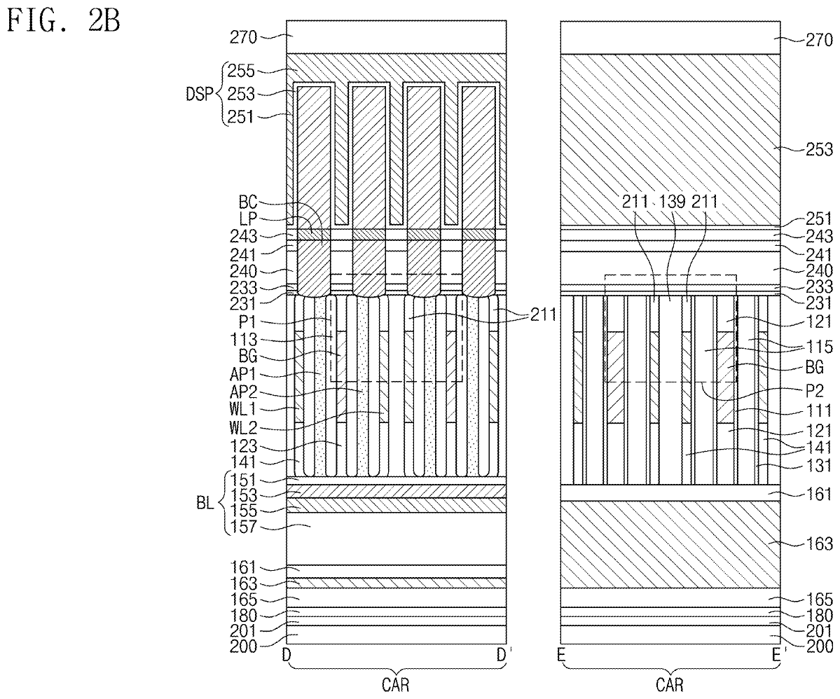

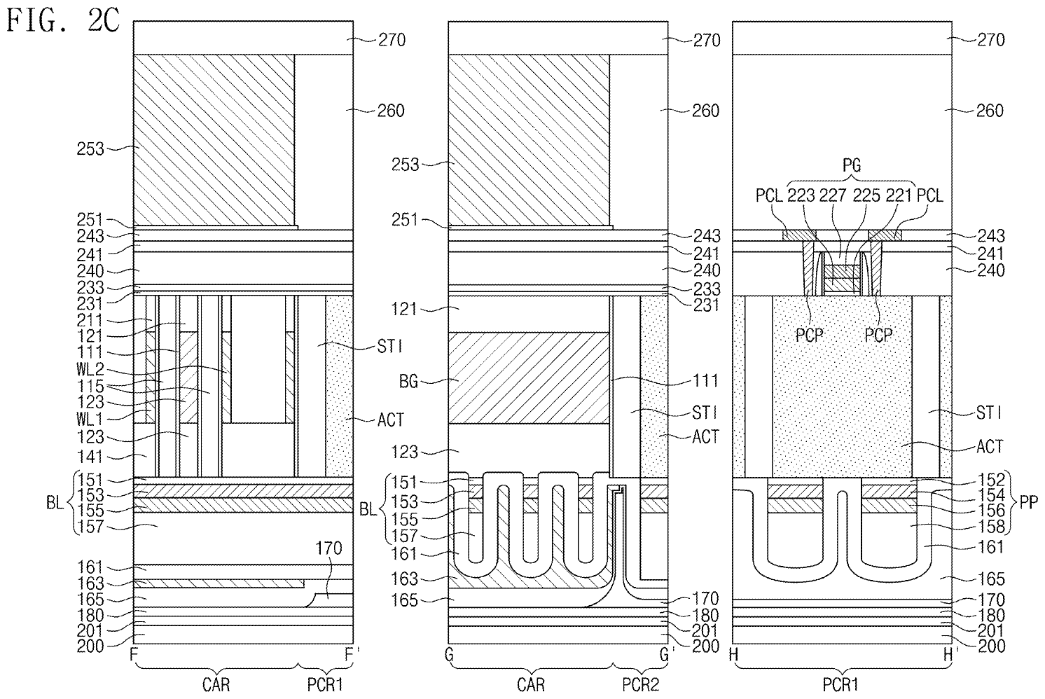

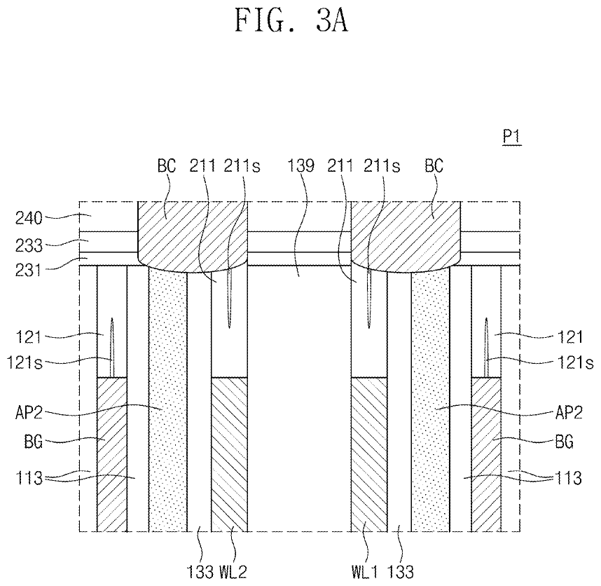

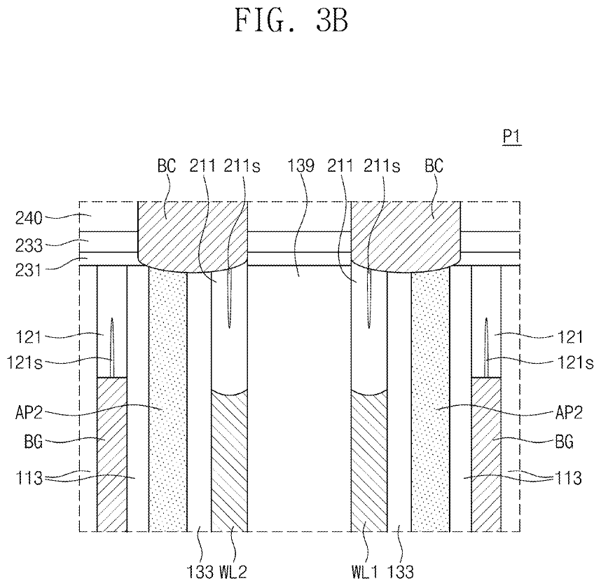

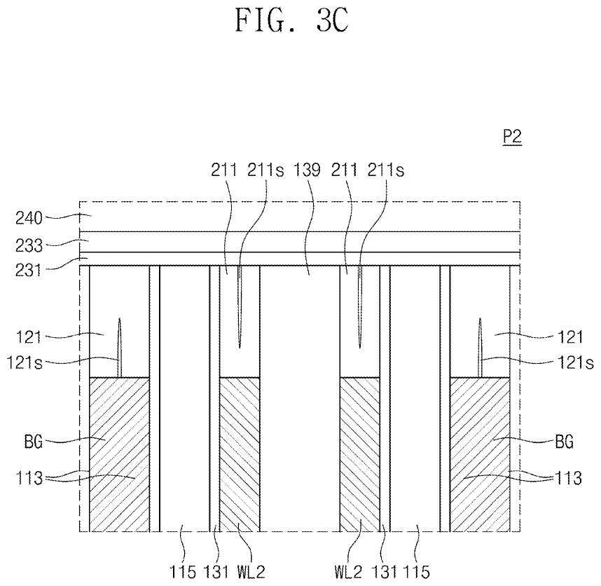

FIG. 1 is a plan view illustrating a semiconductor memory device according to an embodiment. FIGS. 2A, 2B, and 2C are sectional views illustrating a semiconductor memory device according to an embodiment. Here, FIG. 2A illustrates cross-sections taken along lines A-A′, B-B′, and C-C′ of FIG. 1, FIG. 2B illustrates cross-sections taken along lines D-D′ and E-E′ of FIG. 1, and FIG. 2C illustrates cross-sections taken along lines F-F′, G-G′, and H-H′ of FIG. 1. FIGS. 3A and 3B are enlarged sectional views illustrating a portion ‘P1’ of FIG. 2B. FIG. 3C is an enlarged sectional view illustrating a portion ‘P2’ of FIG. 2B.

A semiconductor memory device according to an embodiment may include memory cells, each of which includes a vertical channel transistor (VCT).

Referring to FIGS. 1, 2A, 2B, and 2C, the semiconductor memory device may include a cell array region CAR and first and second peripheral circuit regions PCR1 and PCR2. The cell array region CAR may be adjacent to the first peripheral circuit region PCR1 in a first direction D1 and may be adjacent to the second peripheral circuit region PCR2 in a second direction D2. The first and second directions D1 and D2 may be parallel to a top surface of a substrate 200 and may be perpendicular to each other.

The substrate 200 may be one of a semiconductor substrate (e.g., silicon wafer), an insulating substrate (e.g., glass), or a semiconductor or conductor substrate covered with an insulating material.

Bit lines BL may be disposed on the substrate 200 and in the cell array region CAR to extend in the first direction D1. The bit lines BL may be spaced apart from each other in the second direction D2.

Each of the bit lines BL may include a polysilicon pattern 151, a metal silicide pattern 153, a metal pattern 155, and a hard mask pattern 157, which are sequentially stacked. The polysilicon pattern 151 may be formed of or include doped polysilicon, and the metal silicide pattern 153 may be formed of or include at least one of metal silicide materials (e.g., titanium silicide, cobalt silicide, and nickel silicide). The metal pattern 155 may be formed of or include at least one of conductive metal nitride materials (e.g., titanium nitride and tantalum nitride) or metallic materials (e.g., tungsten, titanium, and tantalum). The hard mask pattern 157 may be formed of or include at least one of insulating materials (e.g., silicon nitride or silicon oxynitride). In an embodiment, the bit lines BL may include at least one of two- and three-dimensional materials. For example, the bit lines BL may be formed of or include a carbon-based two-dimensional material (e.g., graphene), a carbon-based three-dimensional material (e.g., carbon nanotube), or combinations thereof.

In the first and second peripheral circuit regions PCR1 and PCR2, peripheral circuit patterns PP may be disposed on the substrate 200. The peripheral circuit patterns PP may have the same stacking structure as the bit lines BL. In other words, the peripheral circuit patterns PP may include a peripheral poly-silicon pattern 152, a peripheral silicide pattern 154, a peripheral metal pattern 156, and a peripheral hard mask pattern 158, which are sequentially stacked.

A spacer insulating layer 161, a shielding conductive pattern 163, and a capping insulating layer 165 may be disposed between the bit lines BL and the substrate 200.

In detail, the spacer insulating layer 161 may be disposed between the shielding conductive pattern 163 and the bit lines BL. The spacer insulating layer 161 may have a substantially uniform thickness and may cover opposite side surfaces and top surfaces of the bit lines BL. The spacer insulating layer 161 may define gap regions between the bit lines BL. The gap regions of the spacer insulating layer 161 may extend parallel to the bit lines BL and in the first direction D1. The spacer insulating layer 161 may include, for example, a silicon oxide layer, a silicon nitride layer, a silicon oxynitride layer, and/or a low-k dielectric layer.

The spacer insulating layer 161 may extend from the cell array region CAR to the first and second peripheral circuit regions PCR1 and PCR2. The spacer insulating layer 161 may conformally cover the peripheral circuit patterns PP.

The shielding conductive pattern 163 may be disposed between the substrate 200 and the bit lines BL. The shielding conductive pattern 163 may be disposed on the spacer insulating layer 161 to fill the gap regions of the spacer insulating layer 161. In other words, the shielding conductive pattern 163 may include line portions, which are respectively disposed between adjacent ones of the bit lines BL.

The shielding conductive pattern 163 may be formed of or include a conductive material and may include an air gap or a void defined therein. The shielding conductive pattern 163 may be formed of or include at least one of metallic materials (e.g., tungsten (W), titanium (Ti), nickel (Ni), or cobalt (Co)). In an embodiment, the shielding conductive pattern 163 may be formed of or include at least one of conductive two-dimensional (2D) materials (e.g., graphene). The shielding conductive pattern 163 may reduce a coupling noise between adjacent ones of the bit lines BL.

The capping insulating layer 165 may be disposed between the shielding conductive pattern 163 and the substrate 200. The capping insulating layer 165 may have a substantially uniform thickness and may cover the shielding conductive pattern 163. The capping insulating layer 165 may include, for example, a silicon oxide layer, a silicon nitride layer, a silicon oxynitride layer, and/or a low-k dielectric layer.

In the first and second peripheral circuit regions PCR1 and PCR2, the capping insulating layer 165 may be in direct contact with the spacer insulating layer 161.

In the first and second peripheral circuit regions PCR1 and PCR2, a planarization insulating layer 170 may cover the capping insulating layer 165.

A first adhesive layer 180 and a second adhesive layer 201 may be disposed between the substrate 200 and the capping insulating layer 165 and between the substrate 200 and the planarization insulating layer 170. The first and second adhesive layers 180 and 201 may be formed of or include an insulating nitride (e.g., silicon carbon nitride).

On each of the bit lines BL, first and second active patterns AP1 and AP2 may be alternately disposed in the first direction D1. In other words, the first and second active patterns AP1 and AP2 may be two-dimensionally arranged in the first and second directions D1 and D2 that are not parallel to each other. The first active patterns AP1 may be spaced apart from each other by a specific distance in the second direction D2, and the second active patterns AP2 may be spaced apart from each other by a specific distance in the second direction D2.

In an embodiment, the first and second active patterns AP1 and AP2 may be formed of a single-crystalline semiconductor material. For example, the first and second active patterns AP1 and AP2 may be formed of single-crystalline silicon. In the case where the first and second active patterns AP1 and AP2 are formed of the single-crystalline semiconductor material, it may be possible to reduce a leakage current during an operation of the semiconductor memory device.

Each of the first and second active patterns AP1 and AP2 may have a width in the first direction D1, a length in the second direction D2, and a height in a direction perpendicular to the first and second directions D1 and D2. Each of the first and second active patterns AP1 and AP2 may have a substantially uniform width.

Each of the first and second active patterns AP1 and AP2 may have a first or top surface and a second or bottom surface, which are opposite to each other in a vertical direction, and may have substantially the same width on the first and second surfaces. The second surfaces of the first and second active patterns AP1 and AP2 may be in contact with the bit lines BL.

A width of each of the first and second active patterns AP1 and AP2 in the first direction D1 may range from several nanometers to several tens of nanometers. For example, the width of each of the first and second active patterns AP1 and AP2 may range from 1 nm to 30 nm (in particular, from 1 nm to 10 nm). A length of each of the first and second active patterns AP1 and AP2 in the second direction D2 may be larger than a linewidth of the bit line BL.

Each of the first and second active patterns AP1 and AP2 may have a first side surface and a second side surface, which are opposite to each other in the first direction D1. The first side surface of the first active pattern AP1 may be adjacent to a first word line WL1, and the second side surface of the second active pattern AP2 may be adjacent to a second word line WL2.

Each of the first and second active patterns AP1 and AP2 may include a first dopant region adjacent to the bit line BL, a second dopant region adjacent to a contact pattern BC, and a channel region between the first and second dopant regions. The channel regions of the first and second active patterns AP1 and AP2 may be adjacent to the first and second word lines WL1 and WL2. The first and second dopant regions may be dopant-containing regions in the first and second active patterns AP1 and AP2 and may have a doping concentration that is higher than a doping concentration in the channel region. During the operation of the semiconductor memory device, the channel regions of the first and second active patterns AP1 and AP2 may be controlled by the first and second word lines WL1 and WL2 and back-gate electrodes BG.

The back-gate electrodes BG may be disposed on the bit lines BL to be spaced apart from each other by a specific distance in the first direction D1. The back-gate electrodes BG may extend in the second direction D2 to cross the bit lines BL.

Each of the back-gate electrodes BG may be disposed between the first and second active patterns AP1 and AP2, which are adjacent to each other in the first direction D1. That is, the first active pattern AP1 may be disposed at a side of each of the back-gate electrodes BG, and the second active pattern AP2 may be disposed at an opposite side of each of the back-gate electrodes BG.

The back-gate electrode BG may have a first surface that is close to the contact pattern BC, and a second surface that is close to the bit line BL. The first and second surfaces of the back-gate electrode BG may be placed at vertical levels that are different from the first and second surfaces of the first and second active patterns AP1 and AP2.

When measured in the vertical direction, the back-gate electrodes BG may have a height that is smaller than the height of the first and second active patterns AP1 and AP2. In other words, the top surface of the back-gate electrode BG may be lower than the top surfaces of the first and second active patterns AP1 and AP2, and the bottom surface of the back-gate electrode BG may be higher than the bottom surfaces of the first and second active patterns AP1 and AP2.

In an embodiment, the back-gate electrodes BG may be formed of or include at least one of doped polysilicon, conductive metal nitride materials (e.g., titanium nitride and tantalum nitride), metallic materials (e.g., tungsten, titanium, and tantalum), conductive metal silicide materials, or conductive metal oxide materials.

During the operation of the semiconductor memory device, a negative voltage may be applied to the back-gate electrodes BG to increase a threshold voltage of the vertical channel transistor. In this case, it may be possible to prevent a leakage current property of the vertical channel transistor from being deteriorated by a reduction of the threshold voltage of the vertical channel transistor, which could occur when the vertical channel transistor is scaled down.

A first back-gate capping pattern 121 may be disposed on the first surface of the back-gate electrode BG, and a second back-gate capping pattern 123 may be disposed on the second surface of the back-gate electrode BG.

The first back-gate capping pattern 121 may be disposed between the contact patterns BC and the first surface of the back-gate electrode BG, and the second back-gate capping pattern 123 may be disposed between the bit lines BL and the second surface of the back-gate electrode BG. The first and second back-gate capping patterns 121 and 123 may be disposed between the first and second active patterns AP1 and AP2, which are adjacent to each other in the first direction D1.

The first and second back-gate capping patterns 121 and 123 may extend parallel to the back-gate electrodes BG or in the second direction D2. In an embodiment, the first and second back-gate capping patterns 121 and 123 may include a silicon oxide layer, a silicon oxynitride layer, or a silicon nitride layer.

The second back-gate capping pattern 123 may be in contact with the polysilicon patterns 151 of the bit lines BL. A thickness of the second back-gate capping pattern 123 between the bit lines BL may be different from a thickness of the second back-gate capping pattern 123 on the bit lines BL.

The second back-gate capping pattern 123 may have a seam that is formed therein and that extends in the second direction D2. The seam may be vertically spaced apart from the back-gate electrode BG and may be adjacent to the bit lines BL.

Referring to FIG. 3A, the first back-gate capping pattern 121 may have a first seam 121s or a void formed therein. The first seam 121s may extend in the second direction D2. In an embodiment, the first seam 121s may be adjacent to the second surface of the back-gate electrode BG and may be vertically spaced apart from the contact patterns BC.

A liner insulating layer 111 and a back-gate insulating layer 113 may be disposed on opposite side surfaces of the back-gate electrode BG. The liner insulating layer 111 may be disposed between the opposite side surfaces of the back-gate electrode BG and side surfaces of first separation insulating patterns 115. The back-gate insulating layer 113 may be disposed between the opposite side surfaces of the back-gate electrode BG and the side surfaces of the first and second active patterns AP1 and AP2. The back-gate insulating layer 113 may be thicker than the liner insulating layer 111. The liner insulating layer 111 and the back-gate insulating layer 113 may be formed of or include silicon oxide.

The first separation insulating patterns 115 may be disposed between the first active patterns AP1 and between the second active patterns AP2, which are adjacent to each other in the second direction D2. Second separation insulating patterns 139 may be disposed between the first and second word lines WL1 and WL2, which are disposed to face each other. The second separation insulating patterns 139 may extend in the second direction D2. In an embodiment, the first and second separation insulating patterns 115 and 139 may be formed of or include silicon oxide. The first and second separation insulating patterns 115 and 139 may have top surfaces that are substantially coplanar with the top surfaces of the first and second active patterns AP1 and AP2.

The first and second word lines WL1 and WL2 on the bit lines BL may extend in the first direction D1 and may be alternatively arranged in the second direction D2.

The first word line WL1 may be disposed at a side of the first active pattern AP1, and the second word line WL2 may be disposed at an opposite side of the second active pattern AP2. The first and second word lines WL1 and WL2 may be vertically spaced apart from the bit lines BL and the contact patterns BC. In other words, the first and second word lines WL1 and WL2 may be placed between the bit lines BL and the contact patterns BC, when viewed in a vertical view.

Each of the first and second word lines WL1 and WL2 may have a width in the second direction D2. The width on the bit line BL may be different from that on a shielding conductive pattern 173. Portions of the first word lines WL1 may be disposed between the first active patterns AP1, which are adjacent to each other in the first direction D1. Portions of the second word lines WL2 may be disposed between the second active patterns AP2, which are adjacent to each other in the first direction D1.

In an embodiment, the first and second word lines WL1 and WL2 may be formed of or include at least one of doped polysilicon, metallic materials, conductive metal nitride materials, conductive metal silicide materials, conductive metal oxide materials, or combinations thereof.

Adjacent ones of the first and second word lines WL1 and WL2 may have side surfaces facing each other. Each of the first and second word lines WL1 and WL2 may have a first surface, that is close to the bit line BL, and a second surface that is close to the contact pattern BC.

The first surfaces of the first and second word lines WL1 and WL2 may have various shapes. In an embodiment, each of the first and second word lines WL1 and WL2 may have an L-shaped section.

The first and second word lines WL1 and WL2 may have a height that is smaller than the height of the first and second active patterns AP1 and AP2, when measured in the vertical direction. The height of the first and second word lines WL1 and WL2 may be equal to or smaller than the height of the back-gate electrodes BG, when measured in the vertical direction.

Referring to FIG. 3A, the second surfaces of the first and second word lines WL1 and WL2 may be located at substantially the same level as the top surface of the back-gate electrode BG.

Referring to FIG. 3B, the second surfaces of the first and second word lines WL1 and WL2 may be located at a level lower than the top surface of the back-gate electrode BG. The second surfaces of the first and second word lines WL1 and WL2 may have a rounded shape.

First gate insulating patterns 131 may be disposed between the first separation insulating patterns 115 and the first and second word lines WL1 and WL2. Second gate insulating patterns 133 may be disposed between the first and second word lines WL1 and WL2 and the first and second active patterns AP1 and AP2.

In an embodiment, the first gate insulating patterns 131 may be formed of silicon oxide. The second gate insulating patterns 133 may be thicker than the first gate insulating patterns 131. The second gate insulating pattern 133 may cover the first side surface of the first active pattern AP1 and may cover the second side surface of the second active pattern AP2. The second gate insulating pattern 133 may have a substantially uniform thickness.

The second gate insulating patterns 133 may be formed of or include at least one of silicon oxide, silicon oxynitride, or high-k dielectric materials having dielectric constants higher than silicon oxide. The high-k dielectric materials may include metal oxide materials or metal oxynitride materials. For example, the high-k dielectric materials for the second gate insulating patterns 133 may include HfO₂, HfSiO, HfSiON, HfTaO, HfTiO, HfZrO, ZrO₂, Al₂O₃, or combinations thereof, but the inventive concept is not limited to these examples.

First gate capping patterns 141 may be disposed between the first and second word lines WL1 and WL2 and the bit lines BL, and second gate capping patterns 211 may be disposed between the first and second word lines WL1 and WL2 and the contact patterns BC. The first and second gate capping patterns 141 and 211 may be disposed between the second gate insulating patterns 133 and the second separation insulating patterns 139.

The first gate capping patterns 141 may be in contact with the polysilicon patterns 151 of the bit lines BL. The second gate capping patterns 211 may be in contact with portions of the contact patterns BC.

Each of the first gate capping patterns 141 may have a seam formed therein, and here, the seam may be spaced apart from the first and second word lines WL1 and WL2 and may be adjacent to the bit lines BL. In other words, the seam in the first gate capping pattern 141 and the seam in the second back-gate capping pattern 123 may be formed in the same direction and may be located at substantially the same vertical level from the substrate 200.

The first and second gate capping patterns 141 and 211 may extend parallel to the first and second word lines WL1 and WL2 and in the first direction D1. In an embodiment, the first and second gate capping patterns 141 and 211 may be formed of silicon nitride.

Referring to FIG. 3A, each of the second gate capping patterns 211 may have a second seam 211s or a void formed therein. The second seam 211s may be extended in the second direction D2. In an embodiment, the second seam 211s may be formed in an opposite direction to the first seam 121s of the first back-gate capping pattern 121. For example, the second seam 211s may be formed at a vertical level that is different from the first seam 121s of the first back-gate capping pattern 121, when measured from the substrate 200. The second seam 211s may be adjacent to the contact patterns BC and may be vertically spaced apart from the second surfaces of the first and second word lines WL1 and WL2.

First and second etch stop layers 231 and 233 may be disposed in the cell array region CAR to cover the second surfaces of the first and second active patterns AP1 and AP2. The first and second etch stop layers 231 and 233 may be sequentially stacked on the top surfaces of the first back-gate capping patterns 121, the top surfaces of the second gate capping patterns 211, and the top surfaces of the first and second separation insulating patterns 115 and 139. The first and second etch stop layers 231 and 233 may be formed of different insulating materials from each other. For example, the first etch stop layer 231 may be formed of silicon oxide, and the second etch stop layer 233 may be formed of silicon nitride.

An interlayer insulating layer 240 may extend to the first and second peripheral circuit regions PCR1 and PCR2 to cover a top surface of a device isolation layer STI and a peripheral gate electrode PG.

In addition, a peripheral active pattern ACT may be disposed on the substrate 200 in the first and second peripheral circuit regions PCR1 and PCR2. The peripheral active pattern ACT may be formed of or include the same single-crystalline semiconductor material as the first and second active patterns AP1 and AP2 in the cell array region CAR. The peripheral active pattern ACT may have a first surface that is adjacent to the substrate 200, and a second surface that is opposite to the first surface. The first surface of the peripheral active pattern ACT may be substantially coplanar with the first surfaces of the first and second active patterns AP1 and AP2. The second surface of the peripheral active pattern ACT may be substantially coplanar with the second surfaces of the first and second active patterns AP1 and AP2.

The device isolation layer STI may be disposed on the substrate 200 in the first and second peripheral circuit regions PCR1 and PCR2 to penetrate or enclose the peripheral active pattern ACT.

Peripheral transistors may be provided on the second surface of the peripheral active pattern ACT. In an embodiment, the peripheral transistors may constitute row and column decoders, sense amplifiers, or control logics.

In detail, the peripheral gate electrode PG may be disposed on the second surface of the peripheral active pattern ACT. The peripheral gate electrode PG may include a peripheral gate insulating layer 221, a peripheral conductive pattern 223, a peripheral metal pattern 225, and a peripheral mask pattern 227.

The contact patterns BC may be provided to penetrate the interlayer insulating layer 240 and the first and second etch stop layer 231 and 233 and may be coupled to the first and second active patterns AP1 and AP2, respectively. In other words, the contact patterns BC may be coupled to the second dopant regions of the first and second active patterns AP1 and AP2, respectively. A lower width of the contact pattern BC may be larger than an upper width thereof. Adjacent ones of the contact patterns BC may be spaced apart from each other by separation insulating patterns 245. Each of the contact patterns BC may have one of various shapes (e.g., circular, elliptical, rectangular, square, rhombic, and hexagonal shapes), when viewed in a plan view.

The contact patterns BC may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or combinations thereof, as non-limiting examples.

Peripheral contact plugs PCP may be coupled to the peripheral transistors in the first and second peripheral circuit regions PCR1 and PCR2. The peripheral contact plugs PCP may be provided to penetrate a third etch stop layer 241 and the interlayer insulating layer 240 and may be connected to the source/drain impurity regions in the peripheral active pattern ACT.

Landing pads LP may be disposed on the contact patterns BC. Each of the landing pads LP may have one of various shapes (e.g., circular, elliptical, rectangular, square, rhombic, and hexagonal shapes), when viewed in a plan view. The landing pads LP may be arranged in the first and second directions D1 and D2 or in a matrix shape, when viewed in a plan view. The landing pads LP may be provided to have top surfaces that are substantially coplanar with top surfaces of the separation insulating patterns 245.

The landing pads LP may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or combinations thereof, as non-limiting examples.

In the first and second peripheral circuit regions PCR1 and PCR2, peripheral interconnection lines PCL may be disposed in a fourth etch stop layer 243 and may be connected to the peripheral contact plugs PCP.

In the cell array region CAR, data storage patterns DSP may be disposed on the landing pads LP, respectively. The data storage patterns DSP may be electrically connected to the first and second active patterns AP1 and AP2, respectively. The data storage patterns DSP may be arranged in the first and second directions D1 and D2 or in a matrix shape. The data storage patterns DSP may fully or partially overlap with the landing pads LP. Each of the data storage patterns DSP may be in contact with the entire or partial region of the top surface of a corresponding one of the landing pads LP.

In an embodiment, the data storage patterns DSP may be capacitors and may include storage electrodes 251, a plate electrode 255, and a capacitor dielectric layer 253 interposed therebetween. In this case, the storage electrode 251 may be in contact with the landing pad LP and may have one of various shapes (e.g., circular, elliptical, rectangular, square, rhombic, and hexagonal shapes), when viewed in a plan view. The data storage patterns DSP may fully or partially overlap with the landing pads LP. Each of the data storage patterns DSP may be in contact with the entire or partial region of the top surface of a corresponding one of the landing pads LP.

In some implementations, the data storage pattern DSP may be a variable resistance pattern whose resistance can be switched to one of at least two states by an electric pulse applied thereto. For example, the data storage pattern DSP may be formed of or include at least one of phase-change materials whose crystal state can be changed depending on an amount of a current applied thereto, such as, for example, perovskite compounds, transition metal oxides, magnetic materials, ferromagnetic materials, or antiferromagnetic materials.

In the first and second peripheral circuit regions PCR1 and PCR2, a peripheral circuit insulating layer 260 may be disposed on the fourth etch stop layer 243. The peripheral circuit insulating layer 260 may be substantially coplanar with a top surface of the plate electrode 255.

An upper insulating layer 270 may be disposed on the data storage patterns DSP. The upper insulating layer 270 may cover the plate electrode 255 of the data storage patterns DSP and the peripheral circuit insulating layer 260.

Hereinafter, semiconductor memory devices according to various embodiments will be described. In the following description, a previously described element may be identified by the same reference number without repeating an overlapping description thereof, for the sake of brevity.

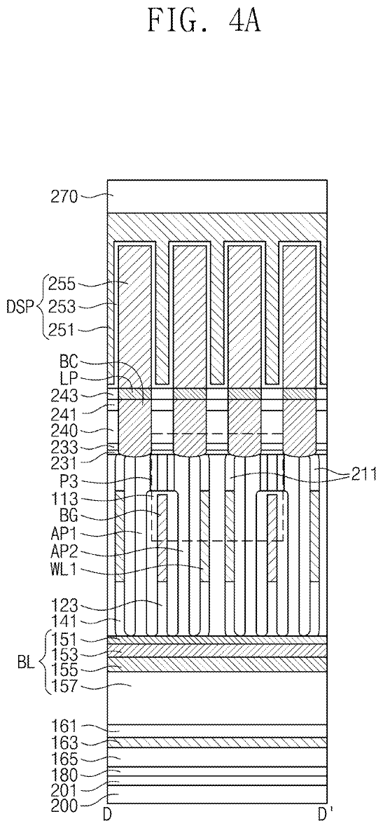

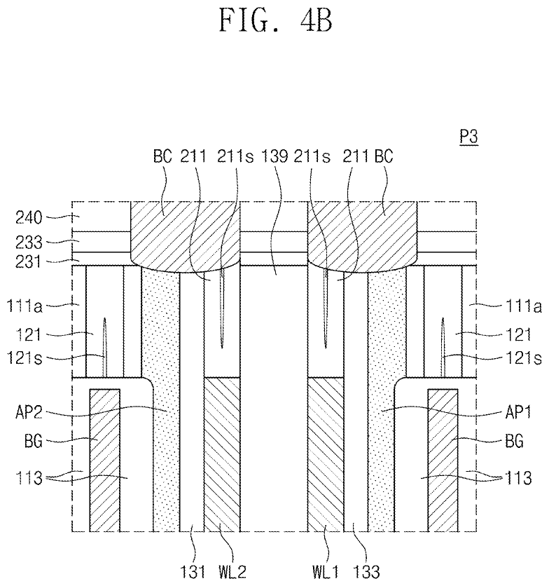

FIG. 4A is a sectional view, which is taken along the line D-D′ of FIG. 1 to illustrate a semiconductor memory device according to an embodiment. FIG. 4B is an enlarged sectional view illustrating a portion ‘P3’ of FIG. 4A.

In the embodiment of FIGS. 4A and 4B, liner insulating patterns 111a may be disposed between the first back-gate capping pattern 121 and the first and second active patterns AP1 and AP2.

The liner insulating patterns 111a may be formed of an insulating material different from the first back-gate capping pattern 121 and may cover opposite side surfaces of the first back-gate capping pattern 121. In addition, a back-gate insulating layer 113 may be extended from regions, which are located on opposite side surfaces of the back-gate electrode BG, to a region, which is located between the first surface of the back-gate electrode BG and the first back-gate capping pattern 121.

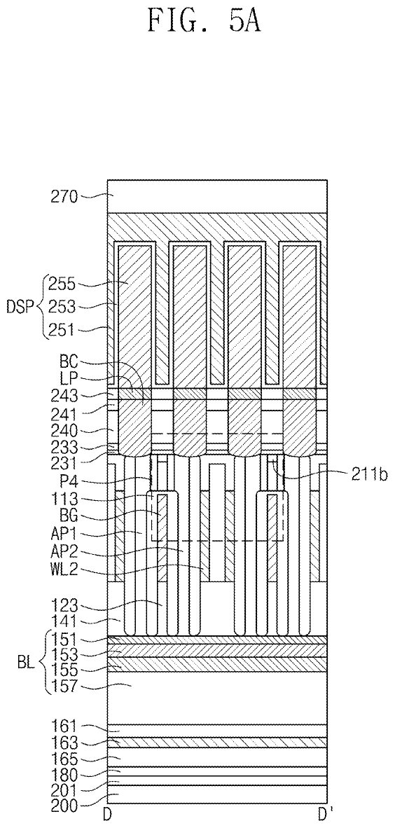

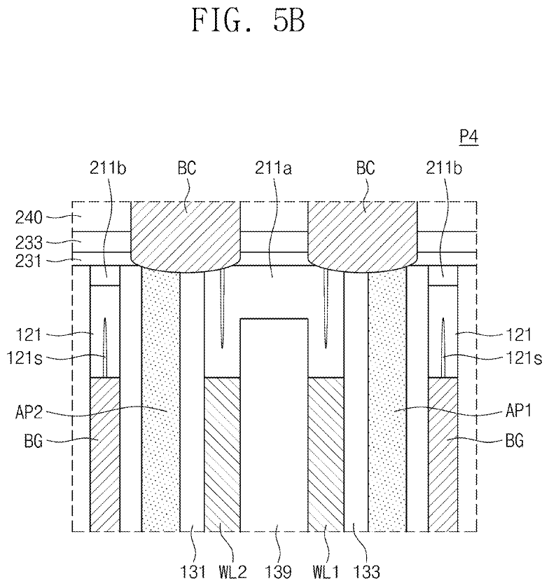

FIG. 5A is a sectional view, which is taken along the line D-D′ of FIG. 1 to illustrate a semiconductor memory device according to an. FIG. 5B is an enlarged sectional view illustrating a portion ‘P4’ of FIG. 5A.

Referring to FIGS. 5A and 5B, each of second gate capping patterns 211a may be provided in common between the contact patterns BC and the first and second word lines WL1 and WL2. That is, each of the second gate capping patterns 211a may include vertical portions that are respectively placed on the first and second word lines WL1 and WL2, and a horizontal portion that connects the vertical portions to each other horizontally. The horizontal portion of each of the second gate capping patterns 211a may be disposed between the second separation insulating pattern 139 and the first etch stop layer 231.

In an embodiment, a seam or a void may be formed in each vertical portion of each second gate capping pattern 211a.

In addition, a dummy capping pattern 211b may be disposed between the first back-gate capping pattern 121 and the first etch stop layer 231. The dummy capping pattern 211b may be formed of the same insulating material as the second gate capping pattern 211a. The dummy capping pattern 211b may have a top surface that is located at substantially the same level as that of the second gate capping pattern 211a.

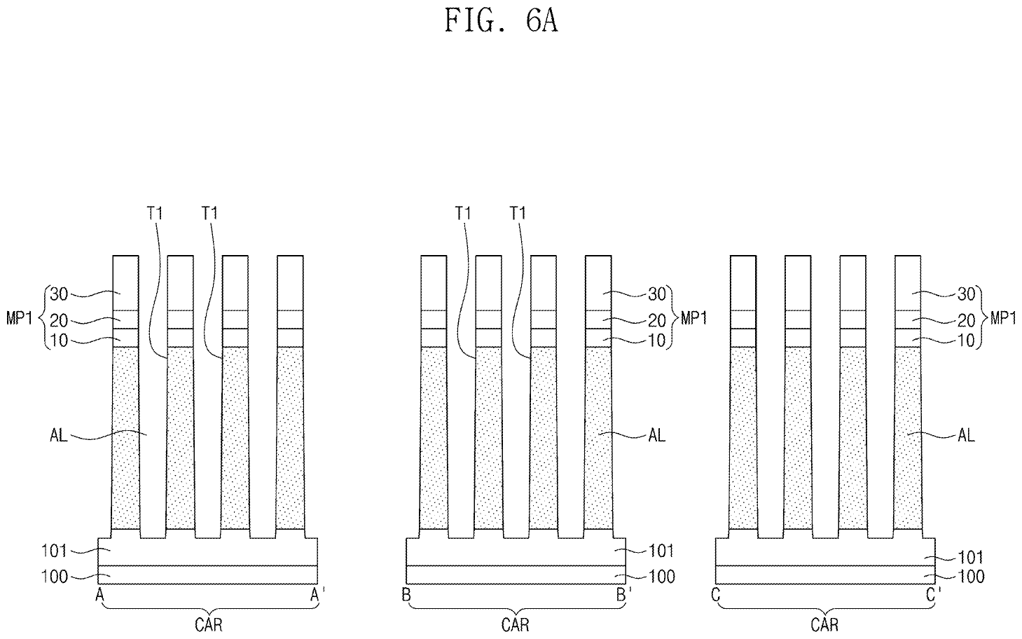

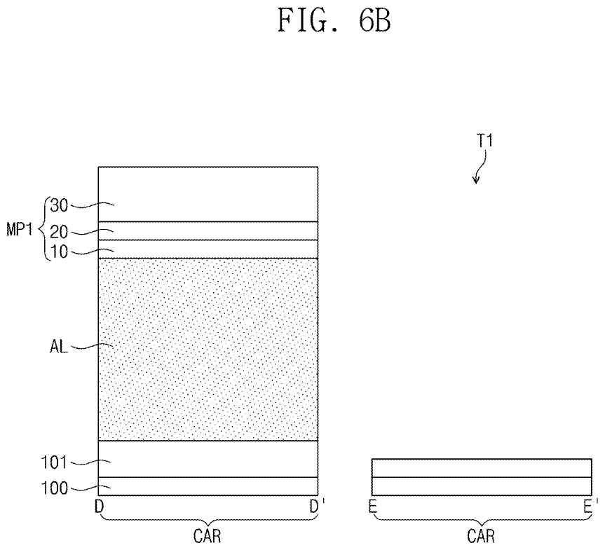

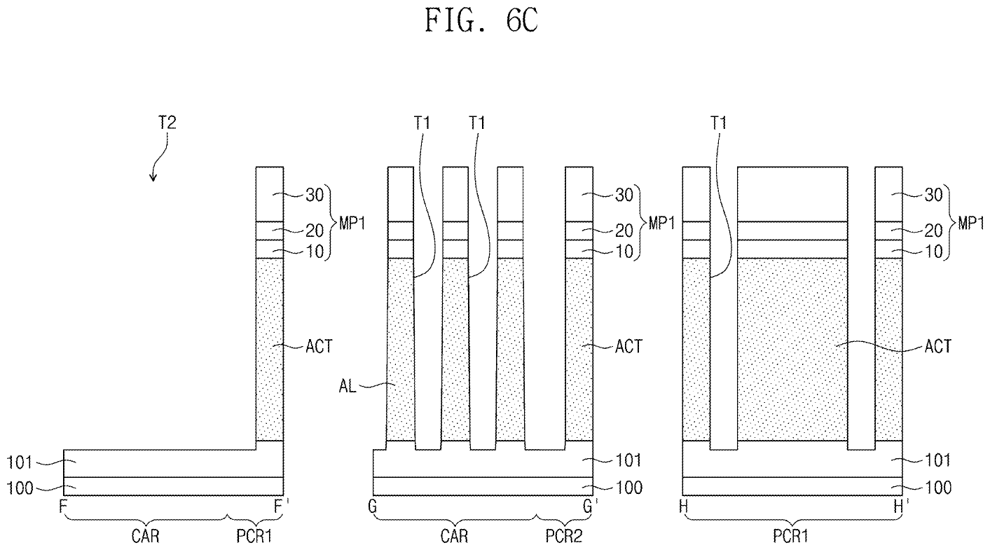

FIGS. 6A to 21A, 6B to 21B, and 6C to 20C are sectional views illustrating a method of fabricating a semiconductor memory device according to an embodiment. Here, FIGS. 6A to 21A illustrate cross-sections taken along the lines A-A′, B-B′, and C-C′ of FIG. 1. FIGS. 6B to 21B illustrate cross-sections taken along the lines D-D′ and E-E′ of FIG. 1. FIGS. 6C to 21C illustrate cross-sections taken along the lines F-F′, G-G′, and H-H′ of FIG. 1.

Referring to FIGS. 1, 6A, 6B, and 6C, a first substrate structure including a first substrate 100, a buried insulating layer 101, and an active layer AL may be prepared.

The buried insulating layer 101 and the active layer AL may be provided on the first substrate 100. The first substrate 100, the buried insulating layer 101, and the active layer AL may constitute a silicon-on-insulator (SOI) substrate.

In an embodiment, the first substrate 100 may be a silicon substrate, a germanium substrate, and/or a silicon-germanium substrate. The first substrate 100 may include the cell array region CAR, the first peripheral circuit region PCR1, which is adjacent to the cell array region CAR in the first direction D1, and the second peripheral circuit region PCR2, which is adjacent to the cell array region CAR in the second direction D2. The first and second directions D1 and D2 may be parallel to a top surface of the first substrate 100 and may not be parallel to each other.

The buried insulating layer 101 may be a buried oxide (BOX) layer, which is formed by a separation-by-implanted oxygen (SIMOX) method or by a bonding and layer-transfer method. Alternatively, the buried insulating layer 101 may be an insulating layer that is formed by a chemical vapor deposition method. The buried insulating layer 101 may include, for example, a silicon oxide layer, a silicon nitride layer, a silicon oxynitride layer, and/or a low-k dielectric layer.

The active layer AL may be a single-crystalline semiconductor layer. The active layer AL may be, for example, a single-crystalline silicon substrate, a germanium substrate, and/or a silicon-germanium substrate. The active layer AL may have a first surface and a second surface, which are opposite to each other. The second surface may be in contact with the buried insulating layer 101.

A first mask pattern MP1 may be formed on the first surface of the active layer AL. The first mask pattern MP1 may have line-shaped openings, which extend from the cell array region CAR in the first direction D1.

The first mask pattern MP1 may include a first mask layer 10, a second mask layer 20, and a third mask layer 30, which are sequentially stacked. Here, the third mask layer 30 may be formed of or include a material having an etch selectivity with respect to the second mask layer 20. The first mask layer 10 may be formed of or include a material having an etch selectivity with respect to the second mask layer 20. In an embodiment, the first mask layer 10 and the third mask layers 30 may be formed of or include silicon oxide, and the second mask layer 20 may be formed of or include silicon nitride.

Thereafter, the active layer AL in the cell array region CAR may be anisotropically etched using the first mask pattern MP1 as an etch mask. Accordingly, first trenches T1, which extend in the first direction D1, may be formed in the active layer AL in the cell array region CAR. The first trenches T1 may be formed to expose the buried insulating layer 101 and may be spaced apart from each other in the second direction D2 by a specific distance. As a result of the formation of the first trenches T1 and the active layer AL may be divided into a plurality of line patterns that extend in the first direction D1.

In an embodiment, the active layer AL in the cell array region CAR may be doped with n- or p-type impurities by performing a doping process, such as a gas phase doping (GPD) process or a plasma doping (PLAD) process, through the first trenches T1.

Furthermore, peripheral active patterns ACT may be formed in the first and second peripheral circuit regions PCR1 and PCR2, when the first trenches T1 are formed.

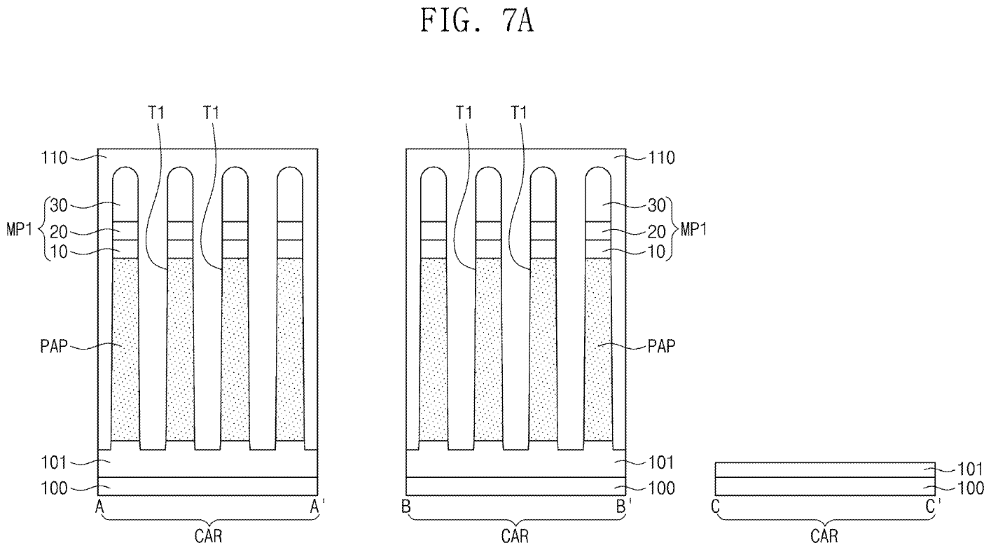

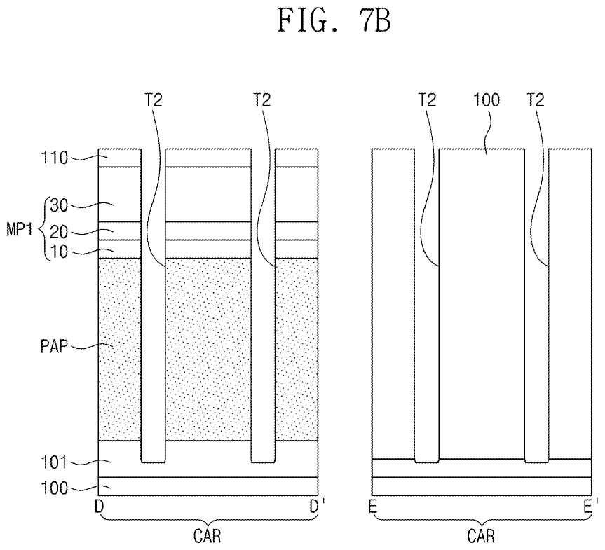

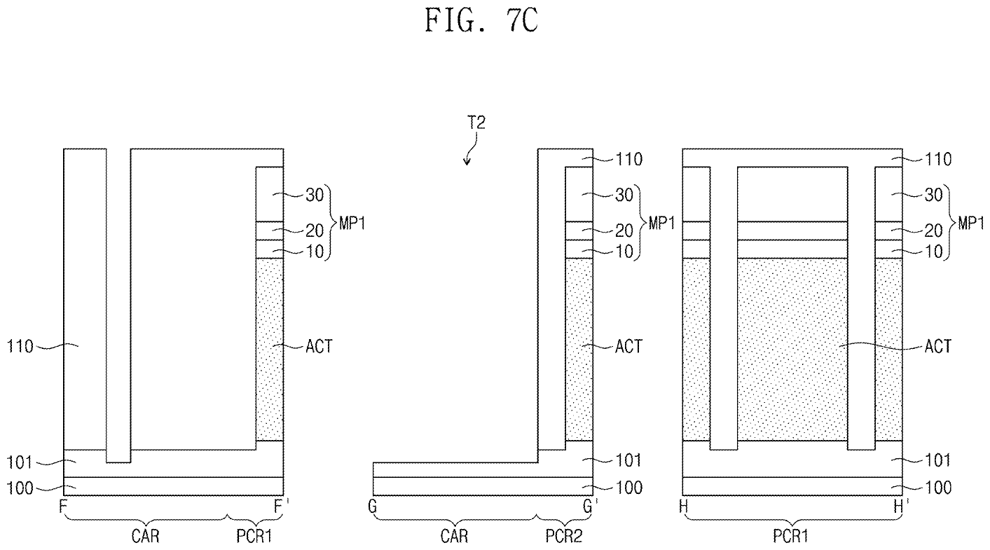

Referring to FIGS. 1, 7A, 7B, and 7C, after the formation of the first trenches T1, a separation insulating layer 110 may be formed to fill the first trenches T1.

The separation insulating layer 110 may be formed of an insulating material (e.g., silicon oxide or silicon nitride). The separation insulating layer 110 may be formed by at least one of low-pressure chemical vapor deposition (LP-CVD), plasma-enhanced chemical vapor deposition (PE-CVD), and atomic layer deposition (ALD) techniques. In the case where the separation insulating layer 110 is formed using the deposition technique, the separation insulating layer 110 may have a discontinuous interface (e.g., seam or void), which is formed in the first trench T1 and extends in the first direction D1.

Next, a mask pattern (not shown) may be formed on the separation insulating layer 110 to cross the first trenches T1. Then, second trenches T2, which extend in the second direction D2, may be formed by patterning the separation insulating layer 110, the first mask pattern MP1, and the active layer AL using the mask pattern. The second trenches T2 may be formed to expose the buried insulating layer 101 and may be spaced apart from each other in the first direction D1 by a specific distance. A top surface of the buried insulating layer 101 may be recessed, when the second trenches T2 are formed. As a result of the formation of the second trenches T2, preliminary active patterns PAP, which are spaced apart from each other in the first and second directions D1 and D2, may be formed.

In an embodiment, after the formation of the preliminary active patterns PAP, the preliminary active patterns PAP, which are exposed through inner surfaces of the second trenches T2, may be doped with impurities by performing the GPD or PLAD process.

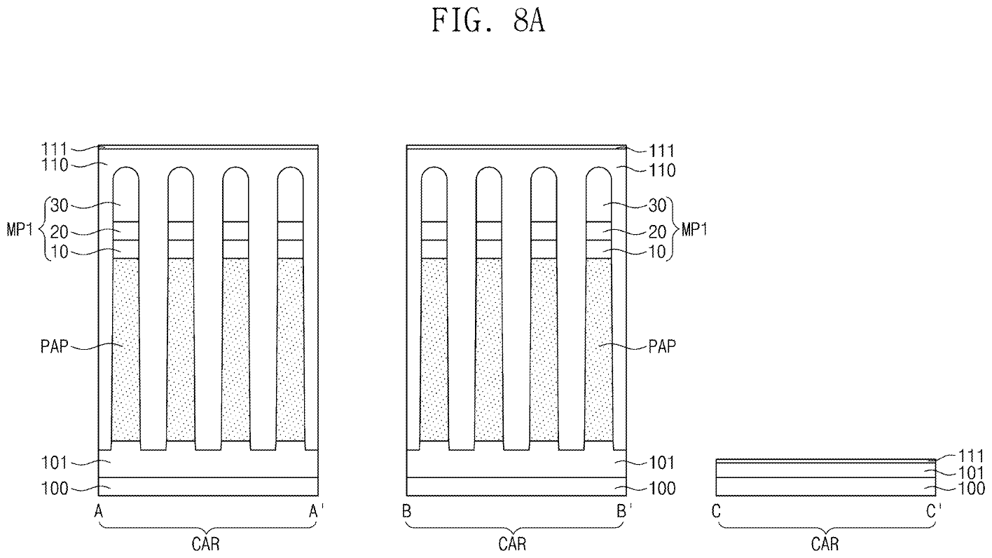

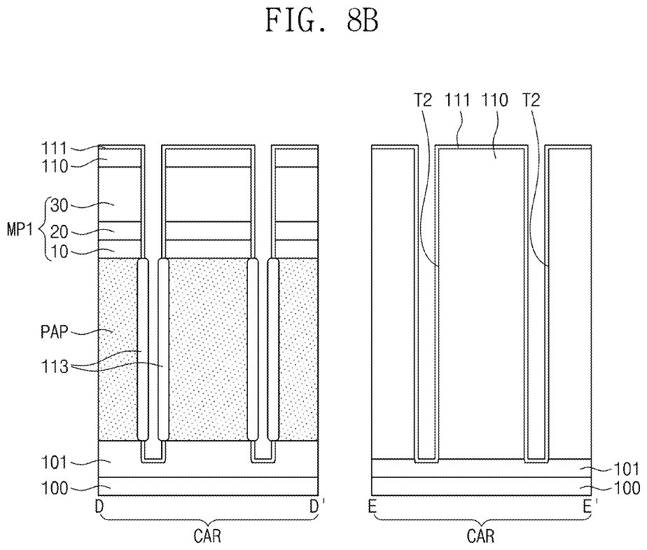

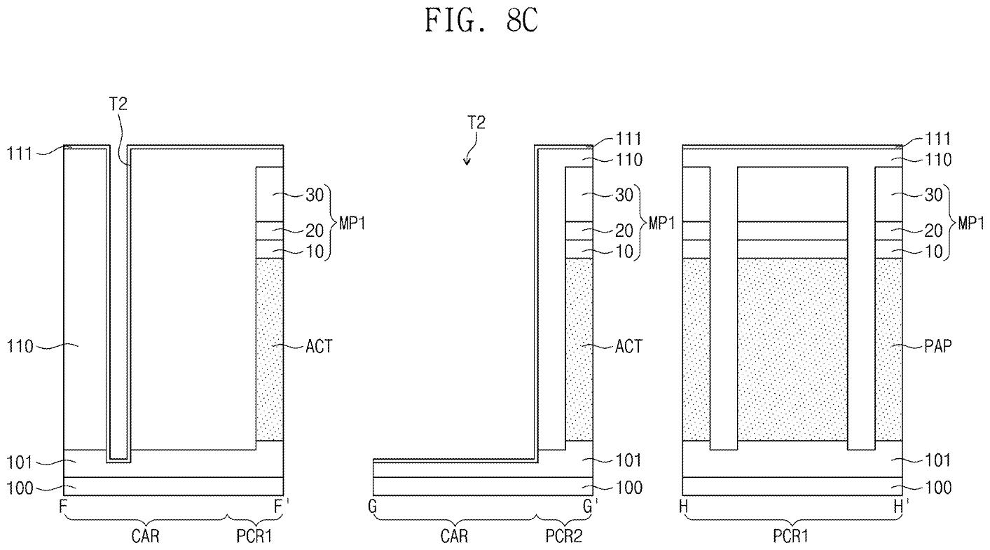

Next, referring to FIGS. 1, 8A, 8B, and 8C, the liner insulating layer 111 may be formed to conformally cover the inner surfaces of the second trenches T2.

The liner insulating layer 111 may be formed by at least one of low-pressure chemical vapor deposition (LP-CVD), plasma-enhanced chemical vapor deposition (PE-CVD), and atomic layer deposition (ALD) techniques. Accordingly, the liner insulating layer 111 may be formed to have a substantially uniform thickness on a top surface of the separation insulating layer 110, a side surface of the separation insulating layer 110 exposed by the second trench T2, and a top surface of the buried insulating layer 101 exposed by the second trench T2. In an embodiment, the liner insulating layer 111 may be formed of or include silicon oxide. In some implementations, the liner insulating layer 111 may be formed of or include at least one of high-k dielectric materials (e.g., hafnium oxide and zirconium oxide).

In an embodiment, a thermal oxidation process may be performed before the formation of the liner insulating layer 111. Accordingly, the back-gate insulating layer 113 may be formed on side surfaces of the preliminary active patterns PAP exposed by the second trenches T2. The back-gate insulating layer 113 may be formed of silicon oxide. The back-gate insulating layer 113 may be thicker than the liner insulating layer 111. In an embodiment, the back-gate insulating layer 113 may be formed of silicon oxide.

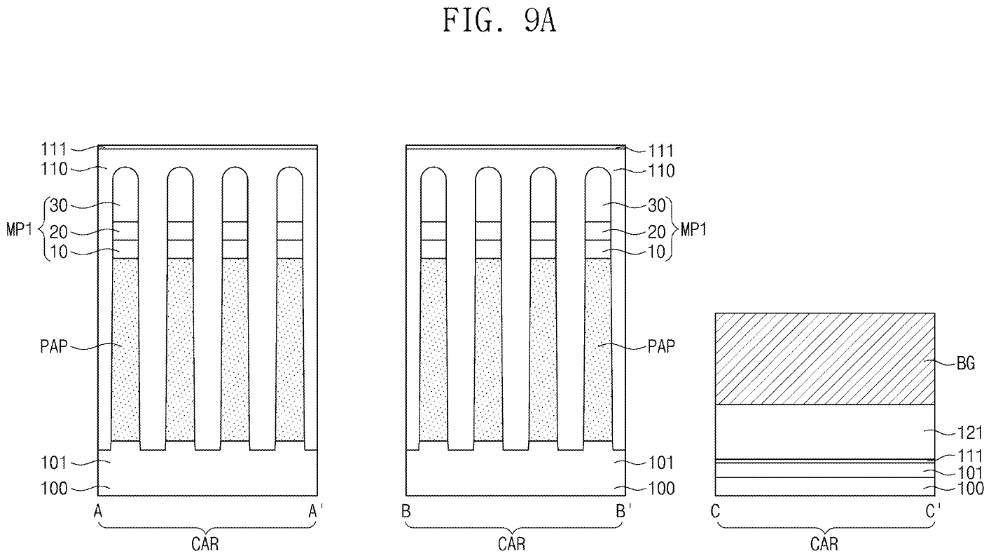

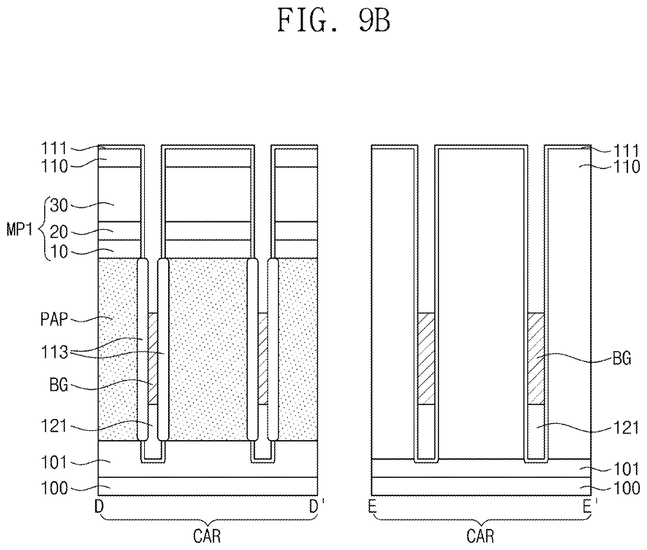

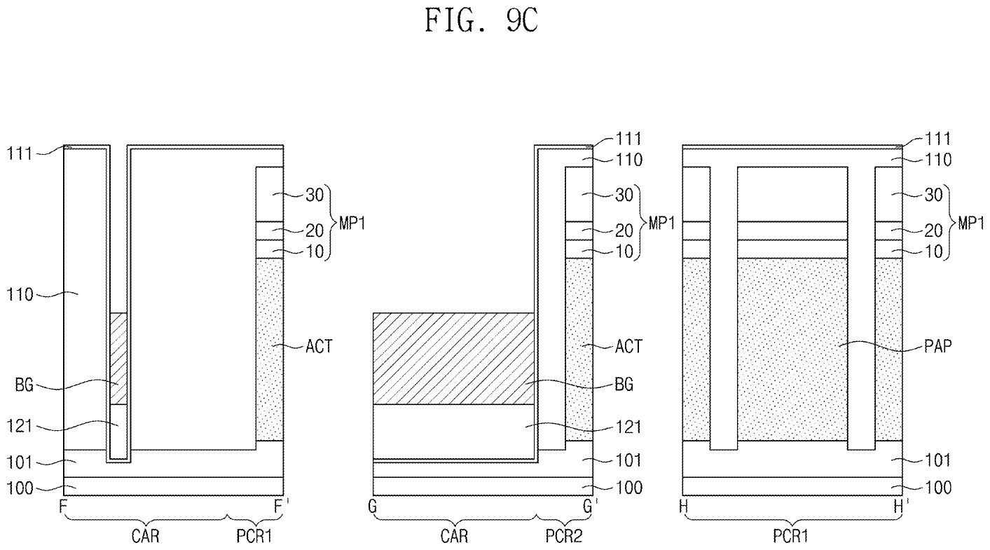

Referring to FIGS. 1, 9A, 9B, and 9C, the first back-gate capping pattern 121 and the back-gate electrode BG may be formed in the second trenches T2 with the liner insulating layer 111 and the back-gate insulating layer 113.

The first back-gate capping pattern 121 may be formed by depositing an insulating material (e.g., silicon nitride) to fill the second trenches T2 with the liner insulating layer 111 and the back-gate insulating layer 113 and isotropically etching the insulating material. The first back-gate capping pattern 121 may be formed to fill a lower portion of the second trench T2 and to expose a portion of a side surface of the back-gate insulating layer 113.

After the formation of the first back-gate capping pattern 121, a gate conductive layer may be deposited to fill the second trenches T2. Next, the gate conductive layer may be isotropically etched to form the back-gate electrodes BG in the second trenches T2, respectively. The first surfaces of the back-gate electrodes BG may be located at a level lower than the first surfaces of the preliminary active patterns PAP.

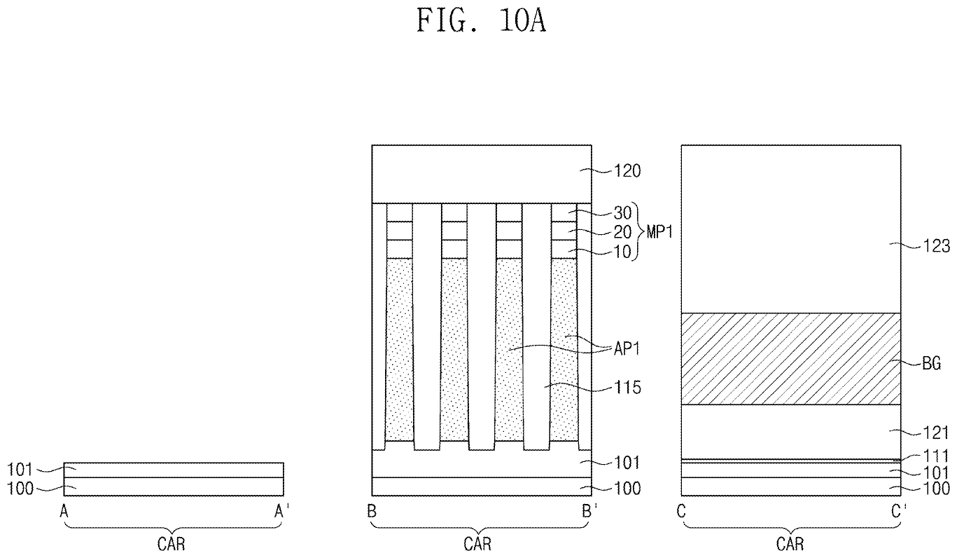

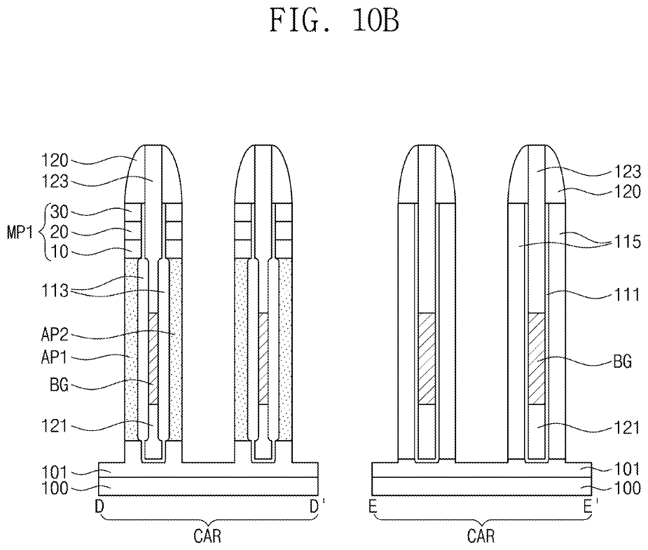

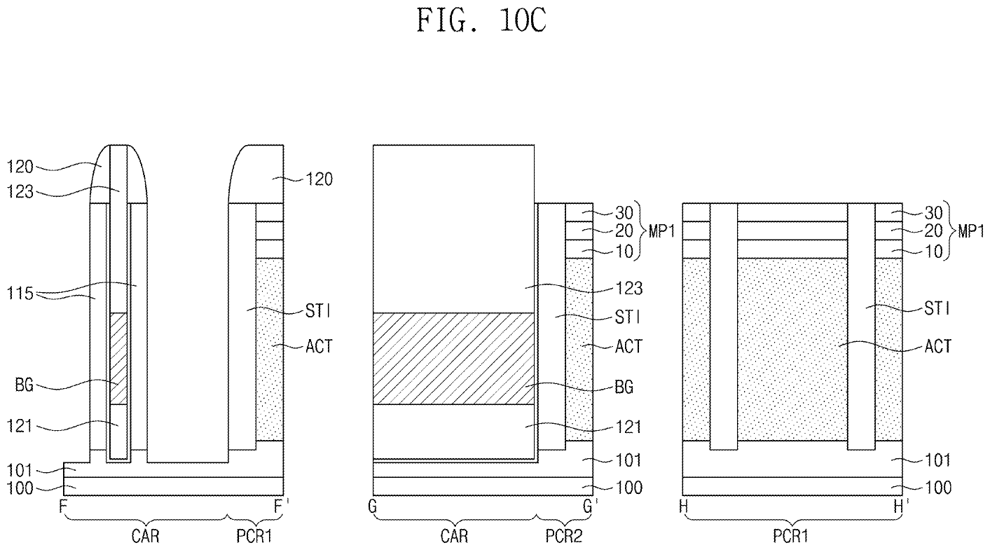

Referring to FIGS. 1, 10A, 10B, and 10C, the second back-gate capping patterns 123 may be formed in the second trenches T2 with the back-gate electrodes BG. The second back-gate capping patterns 123 may be formed by depositing an insulating layer to fill the second trenches T2 with the back-gate electrodes BG and planarizing the insulating layer to expose the top surface of the separation insulating layer 110. In an embodiment, the second back-gate capping patterns 123 may be formed of or include silicon nitride.

After the formation of the second back-gate capping patterns 123, an etch-back process may be performed on a portion of the separation insulating layer 110 and a portion of the third mask layer 30. Accordingly, the separation insulating layer 110 on the third mask layer 30 may be removed, and the second back-gate capping patterns 123 may protrude to a level higher than a top surface of the third mask layer 30.

As a result of the etch-back process on the separation insulating layer 110, the device isolation layer STI may be formed in the first and second peripheral circuit regions PCR1 and PCR2 to enclose the peripheral active patterns ACT, and the top surface of the third mask layer 30 may be exposed.

Next, a spacer layer may be formed to cover the top surface of the third mask layer of the first mask pattern MP1 and the top surfaces of the back-gate capping patterns 123 with a uniform thickness. Here, the width of the active patterns of the vertical channel transistors may be determined by a deposition thickness of the spacer layer.

After the formation of the spacer layer, an anisotropic etching process may be performed on the spacer layer to form a pair of spacers 120 on opposite side surfaces of each of the second back-gate capping patterns 123.

The spacers 120 may be formed of or include at least one of insulating materials. For example, the spacers 120 may be formed of or include at least one of silicon oxide, silicon oxynitride, silicon nitride, silicon carbide, silicon carbon nitride, and combinations thereof. In an embodiment, the spacers 120 may be formed of the same insulating material as the second back-gate capping patterns 123.

Next, an anisotropic etching process using the spacers 120 as an etch mask may be performed on the preliminary active patterns PAP and the separation insulating layer 110. Accordingly, a pair of the first and second active patterns AP1 and AP2, which are spaced apart from each other, may be formed at both sides of each back-gate insulating layer 113. As a result of the formation of the first and second active patterns AP1 and AP2, the buried insulating layer 101 may be exposed. In addition, when the first and second active patterns AP1 and AP2 are formed, the first separation insulating patterns 115 may be formed between adjacent ones of the first active patterns AP1 and between adjacent ones of the second active patterns AP2 in the second direction D2.

The first and second active patterns AP1 and AP2 may be spaced apart from each other in the first and second directions D1 and D2. A third trench may be formed between the first and second active patterns AP1 and AP2, which are adjacent to each other in the first direction D1, and the third trench may be extended in the second direction D2.

After the formation of the first and second active patterns AP1 and AP2, the spacers 120 and upper portions of the second back-gate capping patterns 123 may be removed to expose a top surface of the third mask pattern 30.

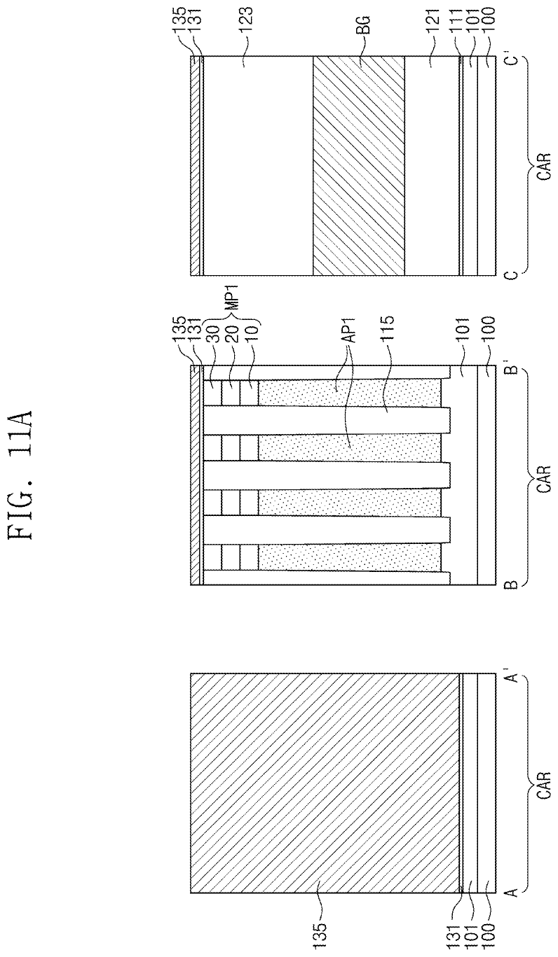

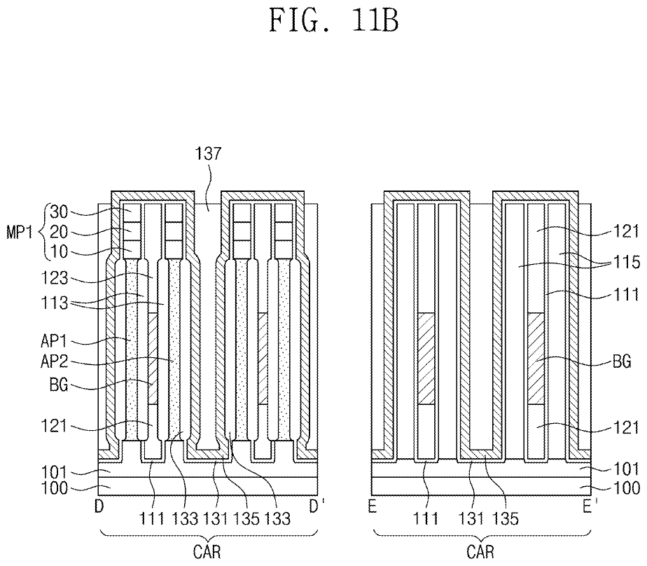

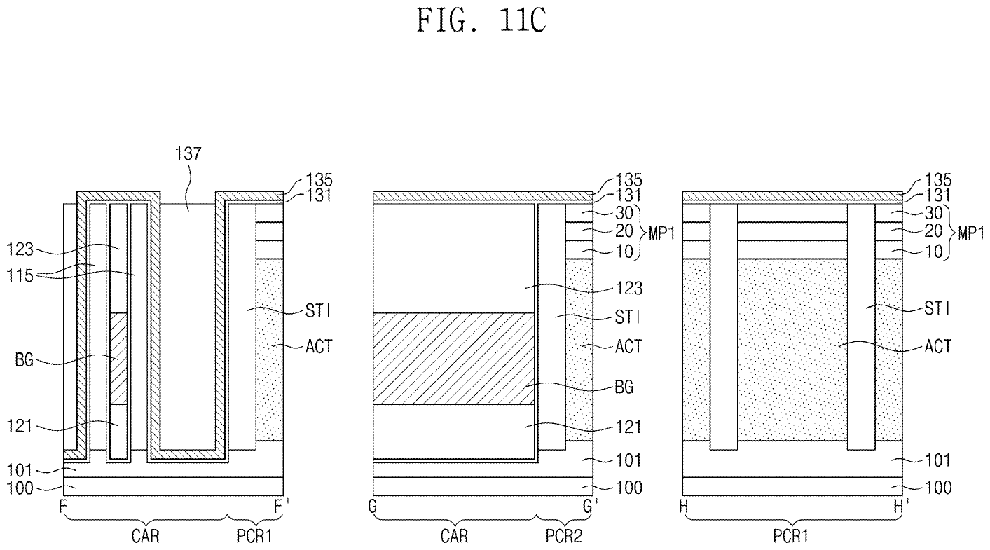

Referring to FIGS. 1, 11A, 11B, and 11C, a first gate insulating layer 131 may be deposited to conformally cover the side surfaces of the first and second active patterns AP1 and AP2, the top surfaces of the second back-gate capping patterns 123, the top surfaces of the first separation insulating patterns 115, and the top surface of the third mask layer 30.

The first gate insulating layer 131 may be formed by at least one of physical vapor deposition (PVD), thermal chemical vapor deposition (thermal CVD), low-pressure chemical vapor deposition (LP-CVD), plasma-enhanced chemical vapor deposition (PE-CVD), or atomic layer deposition (ALD) techniques.

Before the formation of the first gate insulating layer 131, a thermal oxidation process may be performed to form a second gate insulating layer 133 on side surfaces of the first and second active patterns AP1 and AP2. The second gate insulating layer 133 may be formed of silicon oxide and may be thicker than the first gate insulating layer 131.

Next, a gate conductive layer 135 may be formed to cover the first and second gate insulating layers 131 and 133 with a uniform thickness. The gate conductive layer 135 may be formed by at least one of physical vapor deposition (PVD), thermal chemical vapor deposition (thermal CVD), low-pressure chemical vapor deposition (LP-CVD), plasma-enhanced chemical vapor deposition (PE-CVD), or atomic layer deposition (ALD) techniques. A deposition thickness of the gate conductive layer 135 may be smaller than half of the width of the third trench (i.e., half of the distance between the first and second active patterns AP1 and AP2 facing each other). The gate conductive layer 135 may be deposited on the first and second gate insulating layers 131 and 133 to define a gap region in the third trench.

Next, a gap-fill insulating layer 137 may be formed to fill the gap region defined by the gate conductive layer 135. A top surface of the gap-fill insulating layer 137 may be located at a level that is higher than or substantially equal to top surfaces of the second back-gate capping patterns 123. In an embodiment, the gap-fill insulating layer 137 may be formed of or include at least one of silicon nitride, silicon oxynitride, silicon carbide, silicon carbon nitride layer, and combinations thereof.

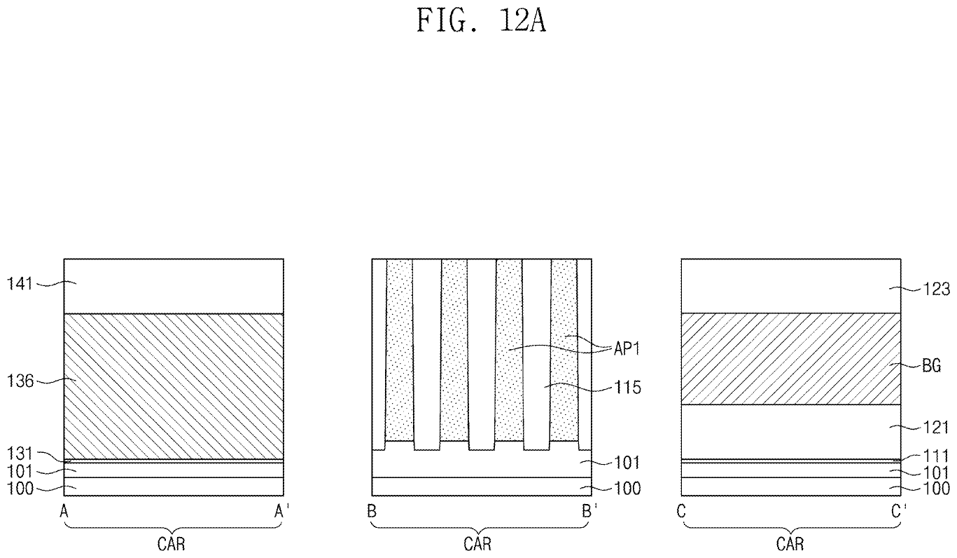

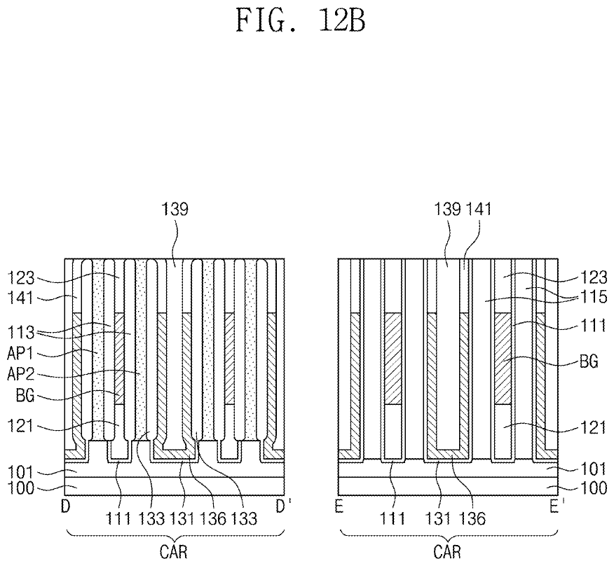

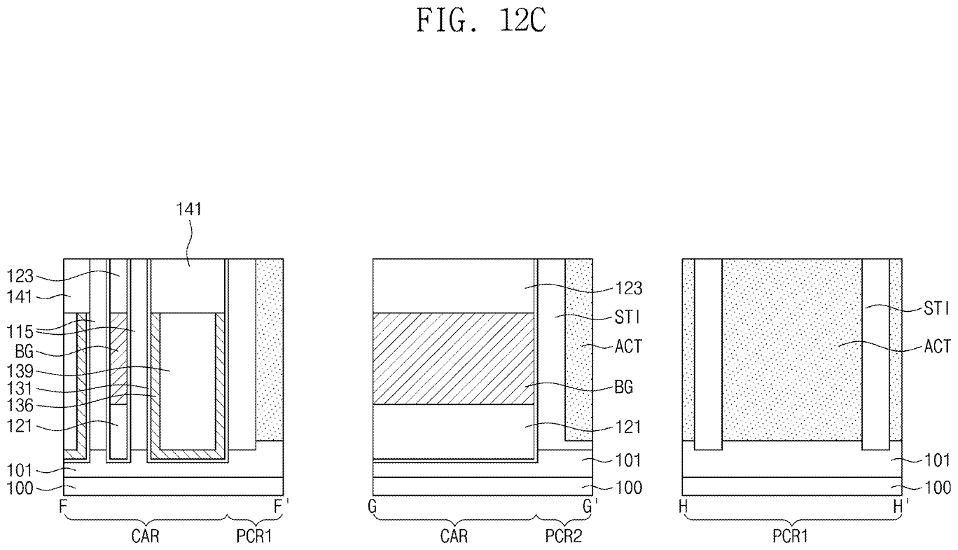

Referring to FIGS. 1, 12A, 12B, and 12C, after the formation of the gap-fill insulating layer 137, preliminary gate conductive patterns 136, which are spaced apart from each other, may be formed by removing an upper portion of the gate conductive layer 135.

The formation of the preliminary gate conductive patterns 136 may include performing an etching or etch-back process on the gate conductive layer 135 to form recess regions between upper side surfaces of the first and second active patterns AP1 and AP2 and a side surface of the gap-fill insulating layer 137. Top surfaces of the preliminary gate conductive patterns 136 may be located at a level lower than the first surfaces of the first and second active patterns AP1 and AP2. Each of the preliminary gate conductive patterns 136 may have a U-shaped section and may extend in the first direction D1. That is, each of the preliminary gate conductive patterns 136 may include vertical portions, which are perpendicular to the top surface of the first substrate 100 and face each other, and a horizontal portion, which is parallel to the top surface of the first substrate 100 and connects the vertical portions to each other.

As a result of the formation of the preliminary gate conductive patterns 136, the gate conductive layer 135 may be removed from the top surface of the first mask pattern MP1 and the top surface of the second back-gate capping pattern 123.

After the formation of the preliminary gate conductive patterns 136, a capping insulating layer (e.g., a silicon nitride layer) may be deposited to fill the recess regions. Thereafter, a planarization process using the second mask pattern 20 as an etch stop layer may be performed on the capping insulating layer and the second back-gate capping patterns 123. The third mask pattern may be removed, during the planarization process.

In addition, a planarization process may be performed on the second mask pattern 20, the capping insulating layer, and the second back-gate capping patterns 123 to expose the first surfaces of the first and second active patterns AP1 and AP2, and a process of etching the first mask pattern 10 may be performed.

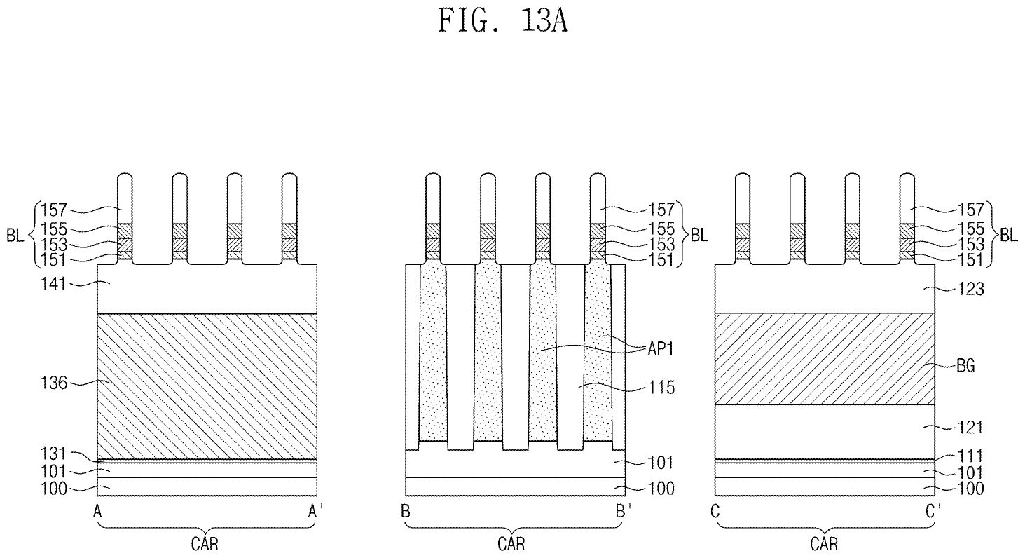

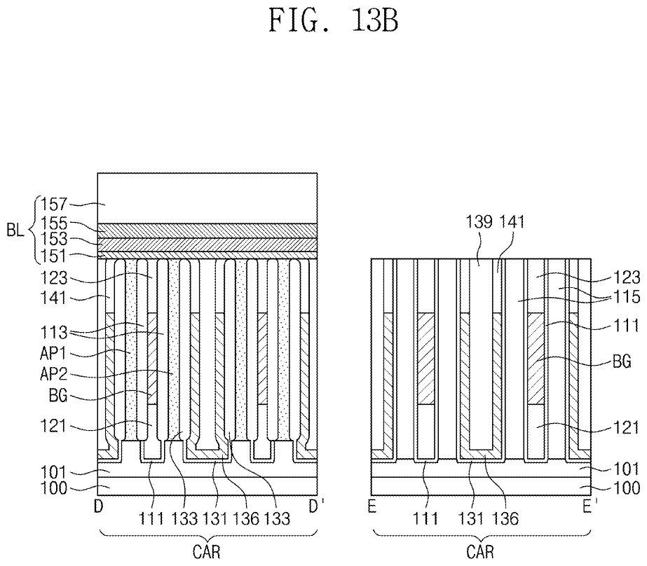

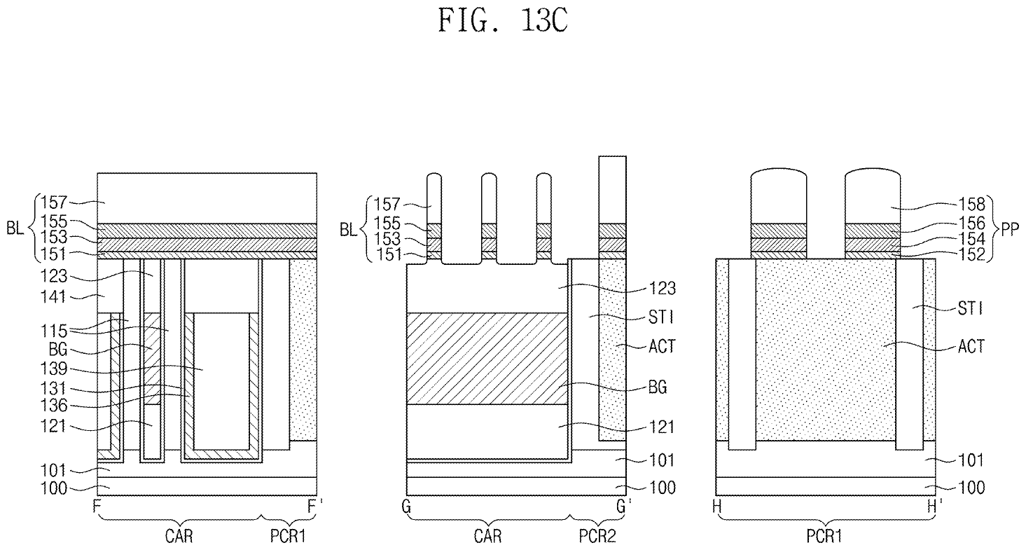

Thus, the first gate capping patterns 141 may be formed on the preliminary gate conductive patterns 136, as shown in FIGS. 1, 13A, 13B, and 13C.

Top surfaces of the first gate capping patterns 141 may be substantially coplanar with the top surfaces of the second back-gate capping patterns 123 and the first surfaces of the first and second active patterns AP1 and AP2.

During the formation of the first gate capping patterns 141, the top surface of the gap-fill insulating layer 137 may be recessed to form the second separation insulating patterns 139. The second separation insulating patterns 139 may extend in the second direction D2, on the preliminary gate conductive patterns 136.

When the first gate capping patterns 141 are formed in the cell array region CAR, the first surface of the peripheral active pattern ACT in the first and second peripheral circuit regions PCR1 and PCR2 may be exposed.

Referring to FIGS. 1, 13A, 13B, and 13C, the bit lines BL, which extend from the cell array region CAR in the first direction D1, may be formed.

The formation of the bit lines BL may include sequentially depositing a poly-silicon layer 151, a metal silicide layer 153, a metal layer 155, and a hard mask layer 157, forming a mask pattern (not shown), which is a line-shaped pattern extending in the second direction D2, on the hard mask layer 157, and sequentially and anisotropically etching the hard mask layer 157, the metal layer 155, the metal silicide layer 153, and the poly-silicon layer 151 using the mask pattern as an etch mask.

Here, the poly-silicon layer 151 may be deposited on the entire top surface of the first substrate 100. The poly-silicon layer 151 may be in contact with the top surfaces of the first and second active patterns AP1 and AP2 in the cell array region CAR, and may be deposited on the peripheral active pattern ACT in the first and second peripheral circuit regions PCR1 and PCR2.

The metal silicide layer 153 may be formed of or include at least one of metal silicide materials (e.g., titanium silicide, cobalt silicide, or nickel silicide).

The metal layer 155 may be formed by depositing at least one of conductive metal nitride materials (e.g., titanium nitride and tantalum nitride) or metallic materials (e.g., tungsten, titanium, and tantalum). The hard mask layer 157 may be formed by depositing at least one of insulating materials (e.g., silicon nitride and silicon oxynitride).

A mask pattern (not shown), which extends in the second direction D2 and has a line shape, may be formed on the hard mask layer 157 Then, the hard mask layer 157, the metal layer 155, the metal silicide layer 153, and the poly-silicon layer 151 may be sequentially and anisotropically etched using the mask pattern. Thus, the bit lines BL, which extend in the second direction D2, may be formed.

When the bit lines BL are formed, the second back-gate capping pattern 123 and the first gate capping patterns 141 may be partially etched.

In an embodiment, when the bit lines BL are formed, the peripheral circuit patterns PP may be formed in the first and second peripheral circuit regions PCR1 and PCR2.

The peripheral circuit patterns PP may have the same stacking structure as the bit lines BL. For example, the peripheral circuit patterns PP may include a poly-silicon pattern 152, a metal silicide pattern 154, a metal pattern 156, and a hard mask pattern 158, which are sequentially stacked.

When the peripheral circuit patterns PP are formed, the hard mask layer 157, the metal layer 155, the metal silicide layer 153, and the poly-silicon layer 151 in the first and second peripheral circuit regions PCR1 and PCR2 may be etched to expose a portion of the device isolation layer STI and a portion of the peripheral active pattern ACT.

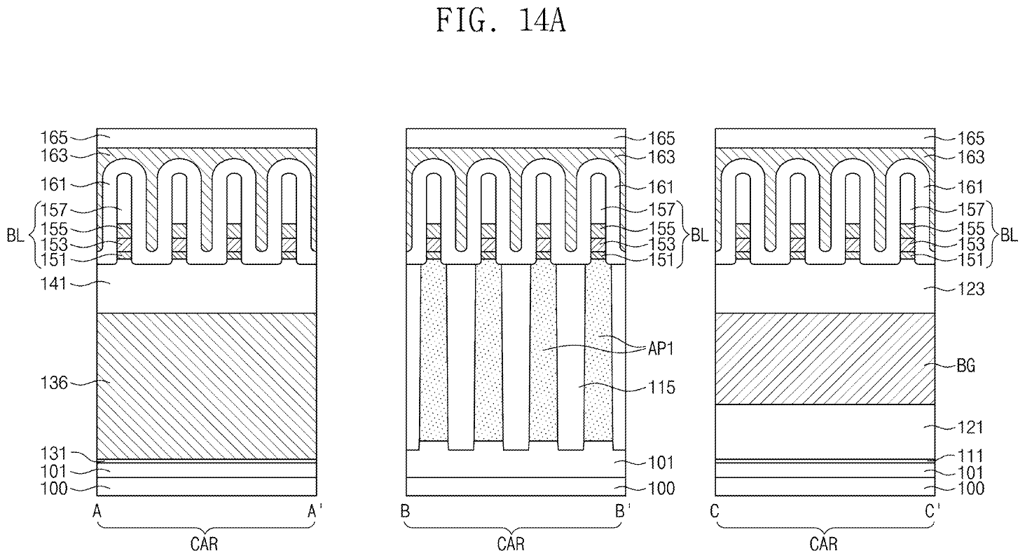

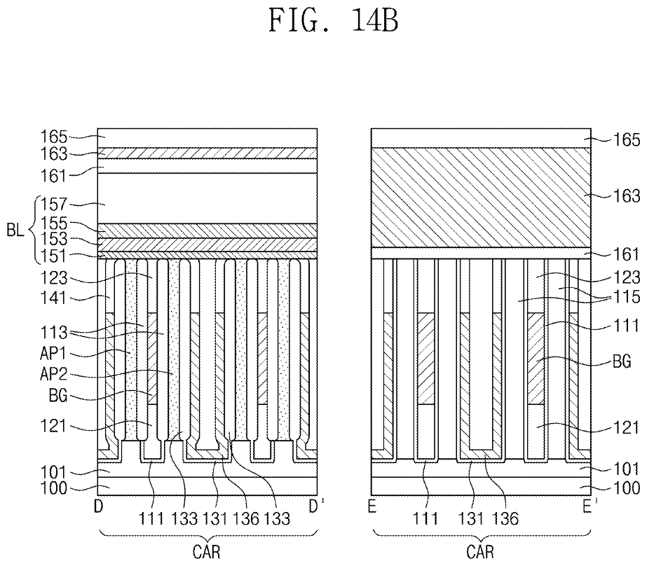

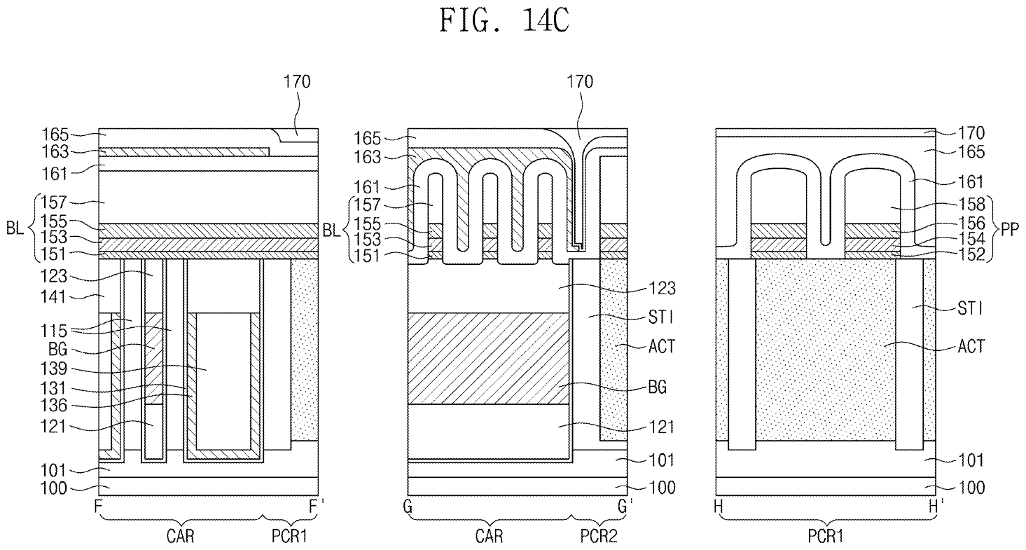

Referring to FIGS. 1, 14A, 14B, and 14C, after the formation of the bit lines BL, the spacer insulating layer 161 may be formed to define a gap region between the bit lines BL.

The spacer insulating layer 161 may be deposited on the first substrate 100 and may have a substantially uniform thickness. A deposition thickness of the spacer insulating layer 161 may be less than half of the distance between adjacent ones of the bit lines BL. In this case, gap regions may be respectively defined between the bit lines BL. The gap region may extend parallel to the bit lines BL or in the second direction D2. In addition, the spacer insulating layer 161 may conformally cover the peripheral circuit patterns PP in the first and second peripheral circuit regions PCR1 and PCR2.

Next, the shielding conductive pattern 163 may be formed on the spacer insulating layer 161.

The formation of the shielding conductive pattern 163 may include depositing a shielding conductive layer on the spacer insulating layer 161 and patterning the shielding conductive layer to remove the shielding conductive layer from the first and second peripheral circuit regions PCR1 and PCR2. Accordingly, after the formation of the shielding conductive pattern 163, the spacer insulating layer 161 in the first and second peripheral circuit regions PCR1 and PCR2 may be exposed.

In the cell array region CAR, the shielding conductive pattern 163 may fill the gap regions, which are defined by the spacer insulating layer 161. In the case where the shielding conductive layer is deposited using a chemical vapor deposition method, a discontinuous interface (e.g., a seam) may be formed in the gap region due to a step coverage property in the chemical vapor deposition method. The shielding conductive pattern 163 may be formed of or include at least one of metallic materials (e.g., tungsten (W), titanium (Ti), nickel (Ni), or cobalt (Co)). In an embodiment, the shielding conductive pattern 163 may be formed of or include at least one of conductive two-dimensional (2D) materials (e.g., graphene).

Thereafter, the capping insulating layer 165 may be formed on the shielding conductive pattern 163. The capping insulating layer 165 may conformally cover the shielding conductive pattern 163 in the cell array region CAR and the spacer insulating layer 161 in the first and second peripheral circuit regions PCR1 and PCR2. In an embodiment, the capping insulating layer 165 may be a silicon nitride layer. A top surface of the capping insulating layer 165 may have a stepwise or uneven portion between the cell array region CAR and the first and second peripheral circuit regions PCR1 and PCR2.

Next, the planarization insulating layer 170 may be formed on the capping insulating layer 165 in the first and second peripheral circuit regions PCR1 and PCR2. The planarization insulating layer 170 may be formed by depositing an insulating material (e.g., silicon oxide). The planarization insulating layer 170 may be formed of or include an insulating material having an etch selectivity with respect to the capping insulating layer 165. As an example, the planarization insulating layer 170 may be one of insulating layers, which are formed by a spin-on-glass (SOG) technique, or a silicon oxide layer. The planarization insulating layer 170 may have a substantially flat top surface, and a top surface of the planarization insulating layer 170 may be substantially coplanar with the top surface of the capping insulating layer 165.

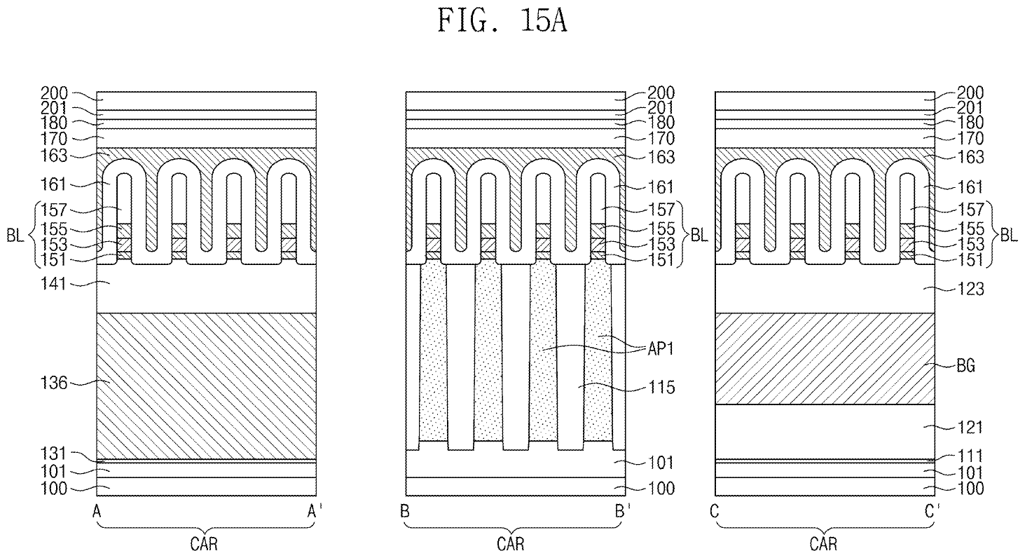

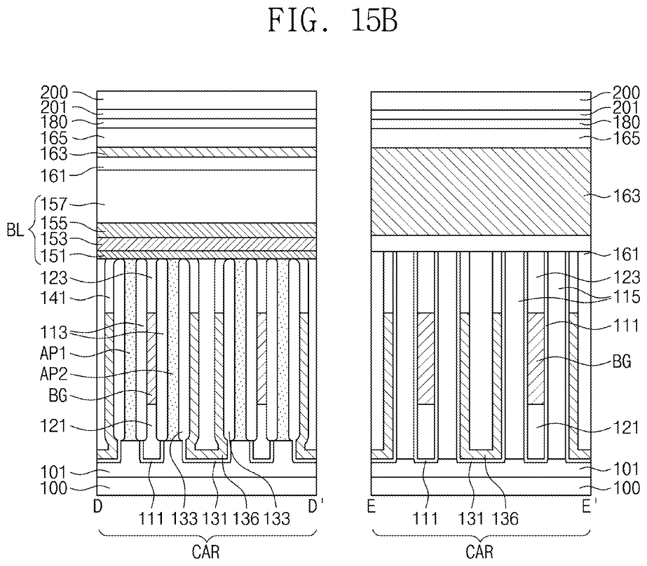

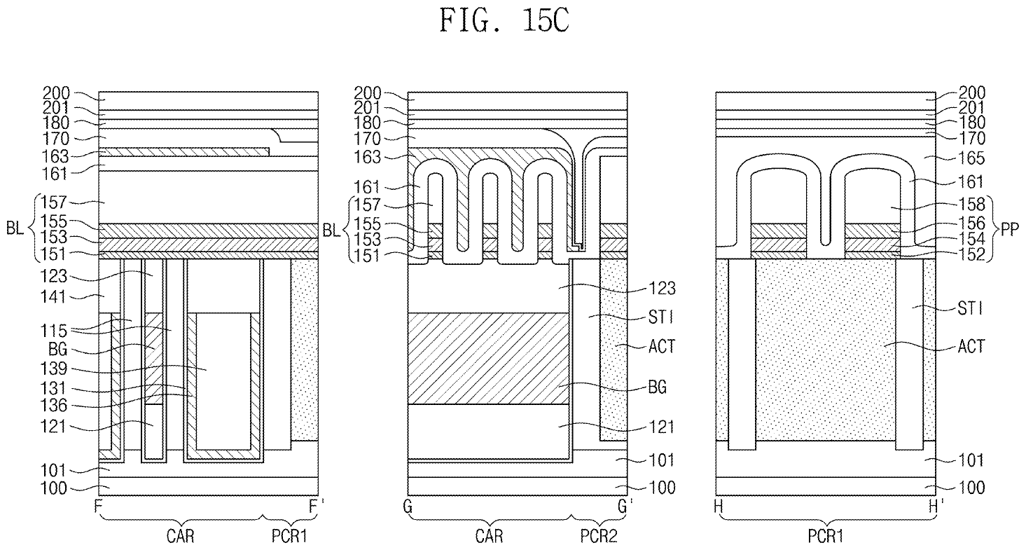

Referring to FIGS. 1, 15A, 15B, and 15C, the first adhesive layer 180 may be formed on the top surface of the capping insulating layer 165 and the top surface of the planarization insulating layer 170.

Thereafter, the second substrate 200 with the second adhesive layer 201 may be bonded to the first adhesive layer 180 on the first substrate 100. The second substrate 200 may be formed of or include single-crystalline silicon or glass (e.g., quartz).

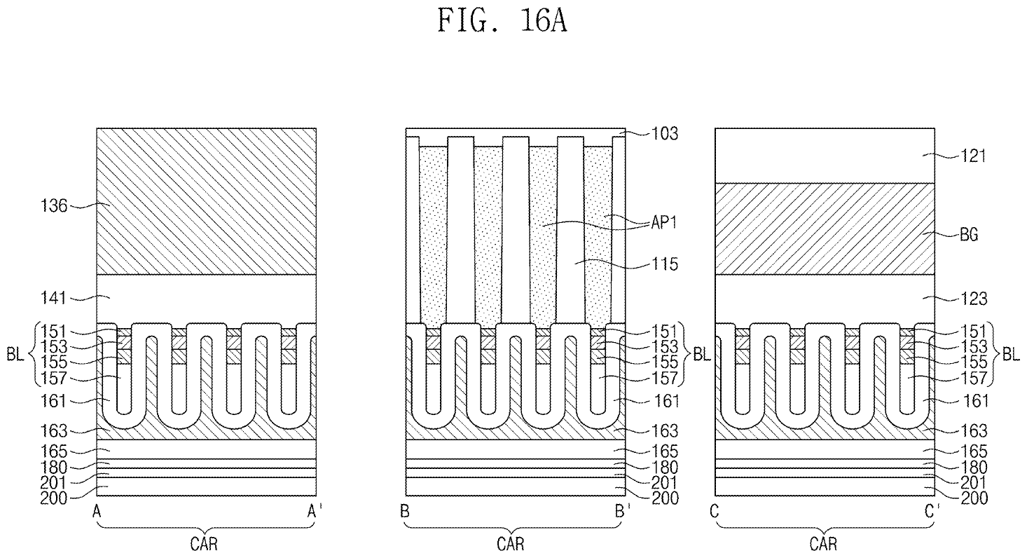

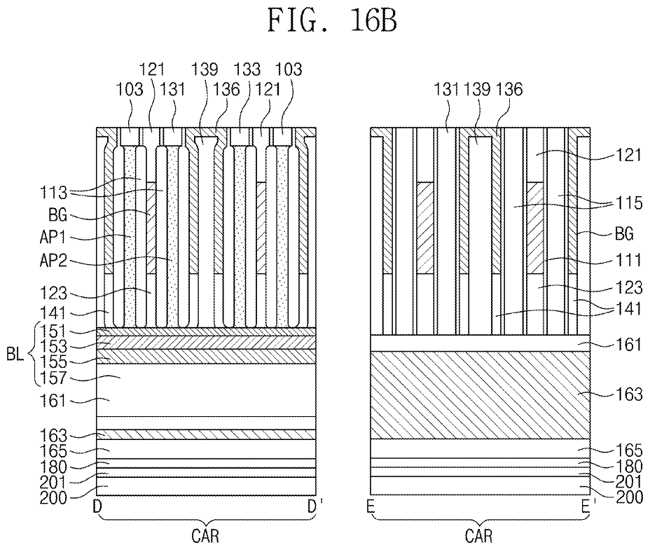

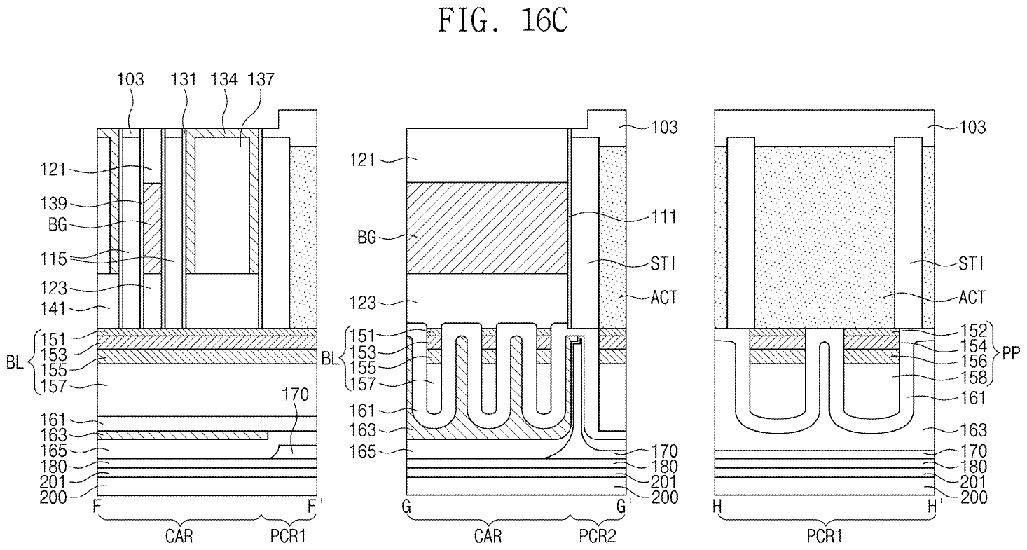

Referring to FIGS. 1, 16A, 16B, and 16C, after the bonding of the second substrate 200, a back-side lapping process may be performed to remove the first substrate 100. The structures on the first substrate 100 may be vertically inverted to perform a process of removing the first substrate 100.

The removal of the first substrate 100 may include sequentially performing a grinding process, a dry etching process, and a wet etching process to expose the horizontal portions of the preliminary gate conductive patterns 136. Accordingly, the buried insulating layer 101 on the horizontal portions of the preliminary gate conductive patterns 136 may be partially removed and buried insulating patterns 103 may be formed on the first and second active patterns AP1 and AP2 and the peripheral active pattern ACT.

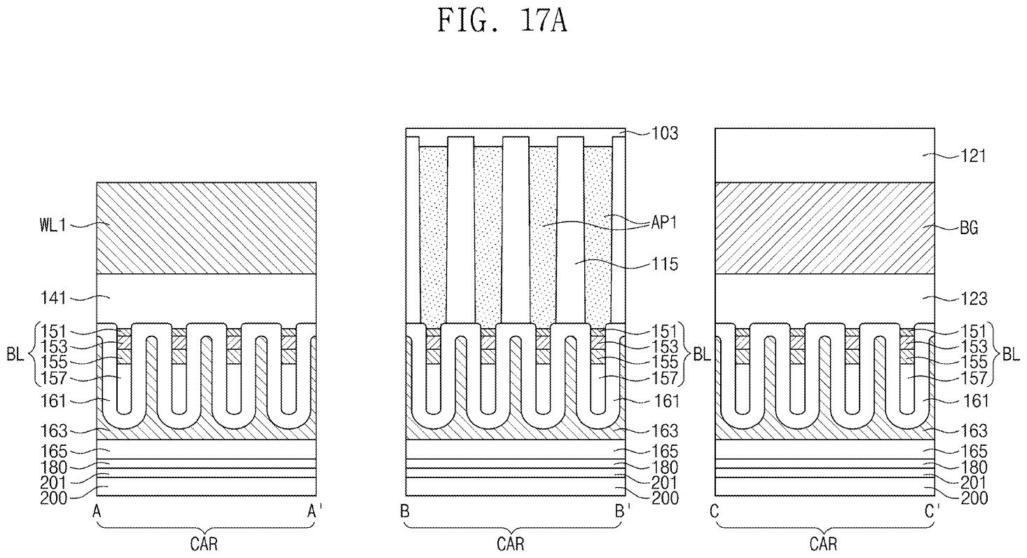

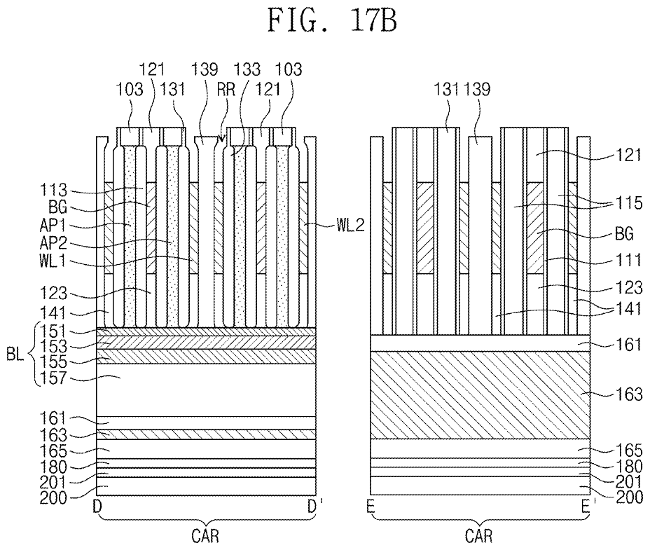

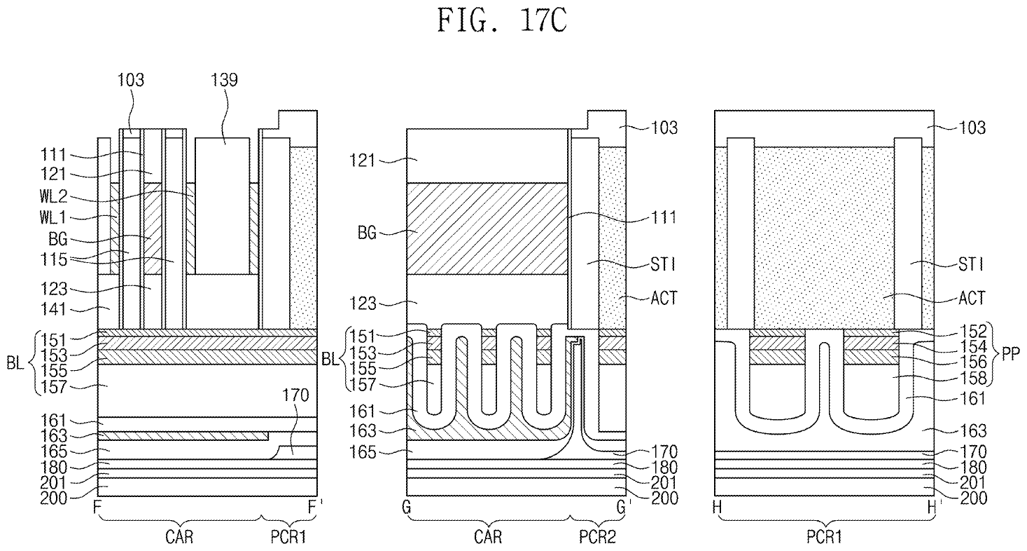

Referring to FIGS. 1, 17A, 17B, and 17C, recess regions RR may be formed by etching the horizontal portions and portions of the vertical portions of the preliminary gate conductive patterns 136. The recess regions RR may extend in the second direction D2 and may expose a portion of the liner insulating layer 111, a portion of the back-gate insulating layer 113, and portions of the second separation insulating patterns 139.

As a result of the formation of the recess regions RR, the first and second word lines WL1 and WL2 may be formed to cross the side surfaces of the first and second active patterns AP1 and AP2.

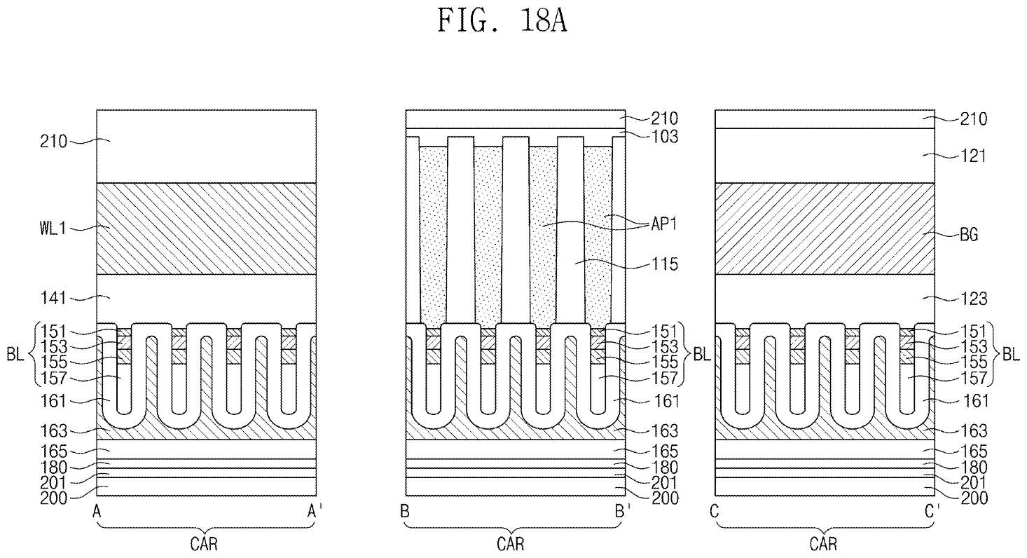

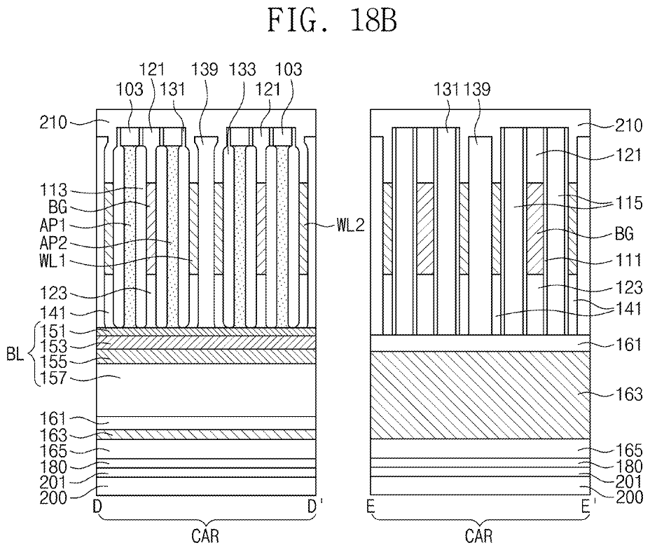

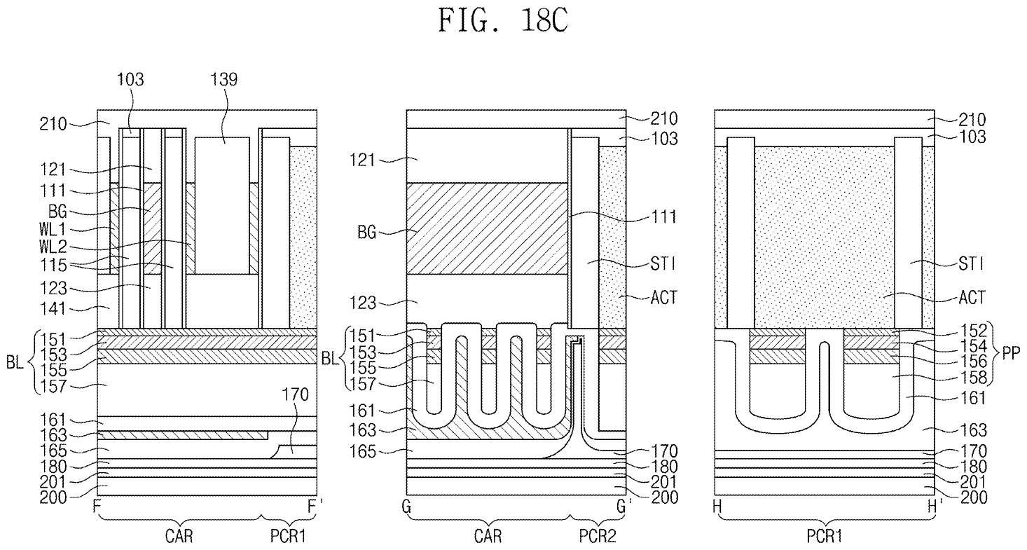

Referring to FIGS. 1, 18A, 18B, and 18C, a second gate capping layer 210 may be formed to fill the recess regions RR. The second gate capping layer 210 may be formed of or include an insulating material having an etch selectivity with respect to the second separation insulating patterns 139. For example, the second gate capping layer 210 may include a silicon oxide layer, a silicon nitride layer, a silicon oxynitride layer, and/or a low-k dielectric layer.

The second gate capping layer 210 may be deposited in the recess regions RR using a chemical vapor deposition method. Due to a step coverage property in the deposition process, a discontinuous interface (e.g., a seam) may be formed in the recess regions RR. The seam in the second gate capping layer 210 may be extended in the second direction D2 and may be vertically spaced apart from the top surfaces of the first and second word lines WL1 and WL2.

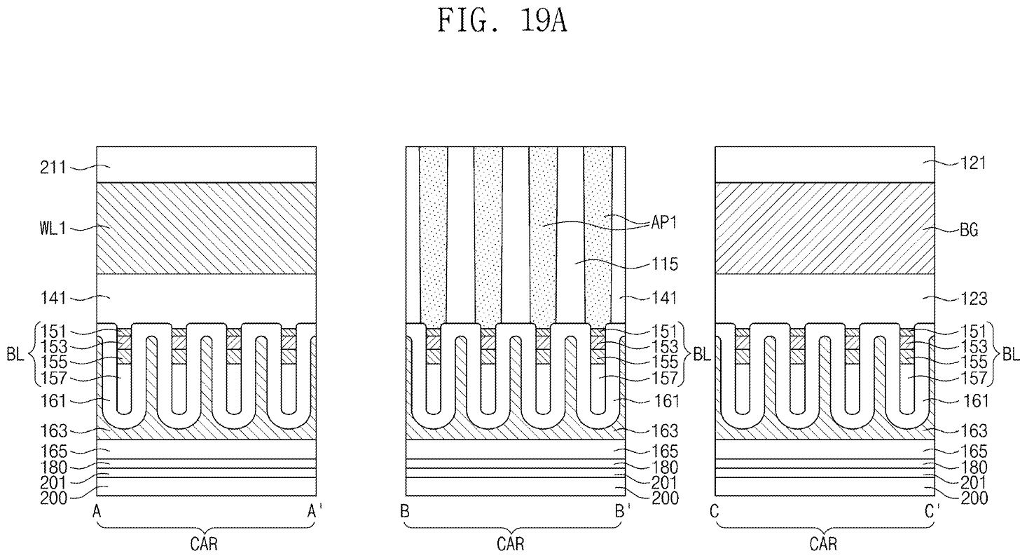

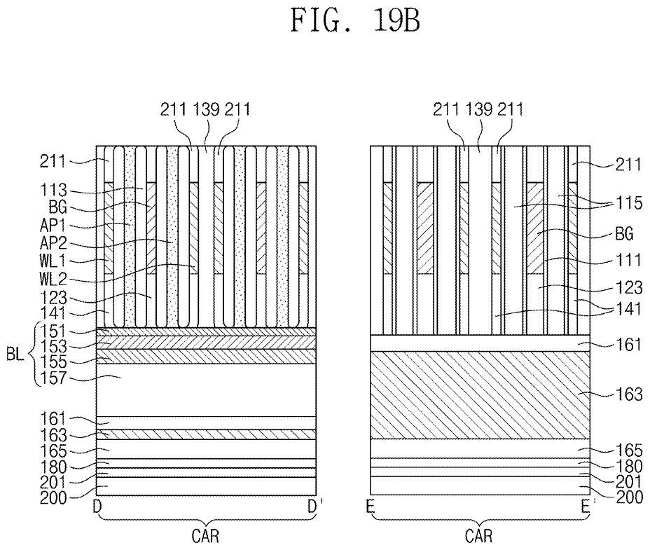

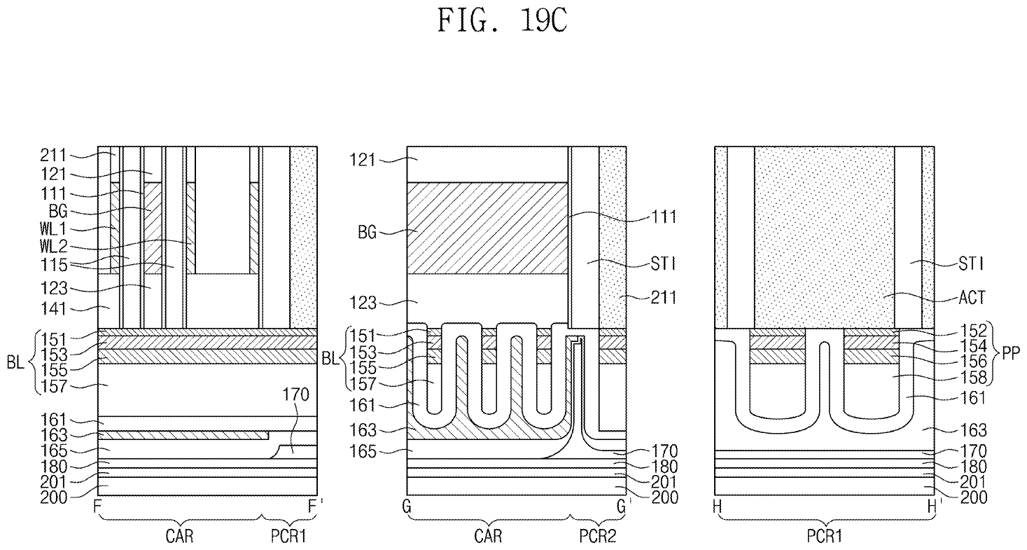

Referring to FIGS. 1, 19A, 19B, and 19C, after the formation of the second gate capping layer 210, a planarization process may be performed on the second gate capping layer 210 to expose the top surfaces of the first and second active patterns AP1 and AP2. Thus, the second gate capping patterns 211 may be formed on the first and second word lines WL1 and WL2, respectively.

The buried insulating pattern 103 may be removed during or after the formation of the second gate capping patterns 211. Thus, the first and second active patterns AP1 and AP2 and the first back-gate capping patterns 121 may be exposed to the outside, in the cell array region CAR. Furthermore, the top surface of the peripheral active pattern ACT may be exposed to the outside, in the first and second peripheral circuit regions PCR1 and PCR2.

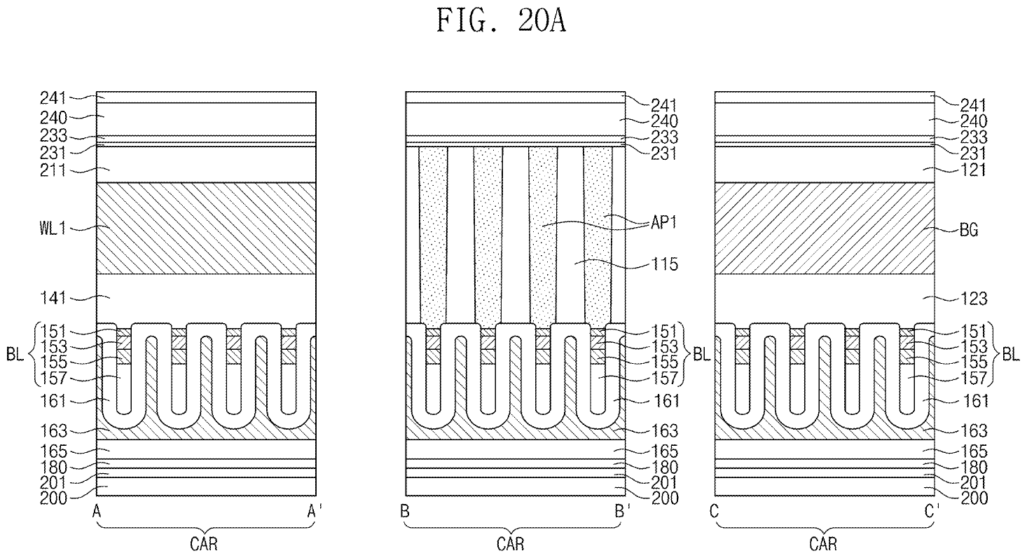

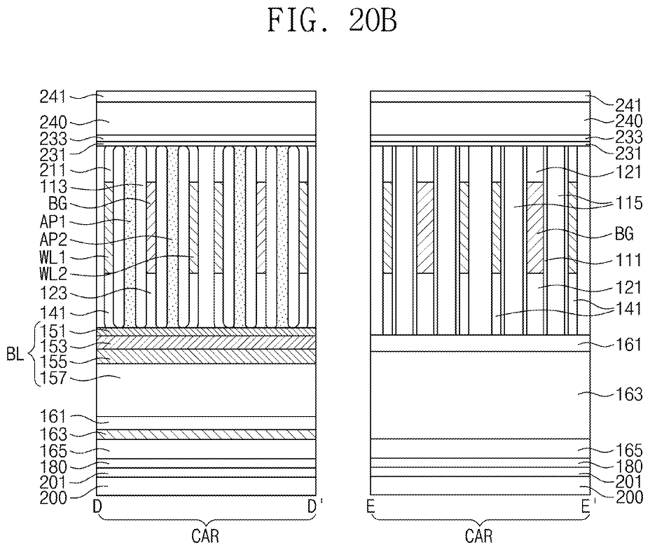

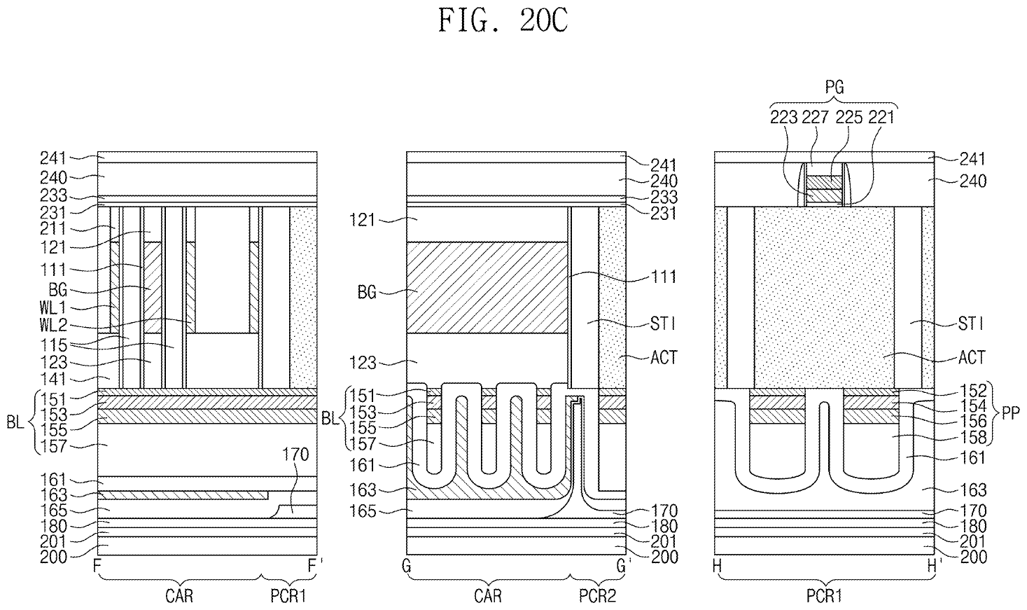

Referring to FIGS. 1, 20A, 20B, and 20C, the first and second etch stop layers 231 and 233 may be sequentially formed on the second substrate 200. The first etch stop layer 231 may be formed of silicon oxide and may be deposited on the first and second active patterns AP1 and AP2, the first and second separation insulating patterns 115 and 139, and the first back-gate capping patterns 121. The second etch stop layer 233 may be formed of a material (e.g., silicon nitride) having an etch selectivity with respect to the first etch stop layer 231.

Next, a patterning process may be performed on the first and second etch stop layers 231 and 233, and thus, the peripheral active patterns ACT in the first and second peripheral circuit regions PCR1 and PCR2 may be exposed.

Thereafter, a peripheral transistor may be formed on the peripheral active patterns ACT. In detail, the peripheral gate electrode PG may be formed on the peripheral active patterns ACT in the first and second peripheral circuit regions PCR1 and PCR2 Then, insulating spacers may be formed on opposite side surfaces of the peripheral gate electrode PG. In addition, source/drain regions may be formed by injecting impurities into portions of the peripheral active pattern ACT that are at both sides of the peripheral gate electrode PG. The peripheral gate electrode PG may include the peripheral gate insulating pattern 221, the peripheral conductive pattern 223, the peripheral metal pattern 225, and the peripheral mask pattern 227, which are sequentially stacked.

Next, the interlayer insulating layer 240 and the third etch stop layer 241 may be formed in the cell array region CAR and a peripheral circuit region PCR. The interlayer insulating layer 240 may be formed by depositing an insulating material and planarizing the insulating material to expose the top surface of the peripheral gate electrode PG. The third etch stop layer 241 may be formed of or include an insulating material having an etch selectivity with respect to the interlayer insulating layer 240.

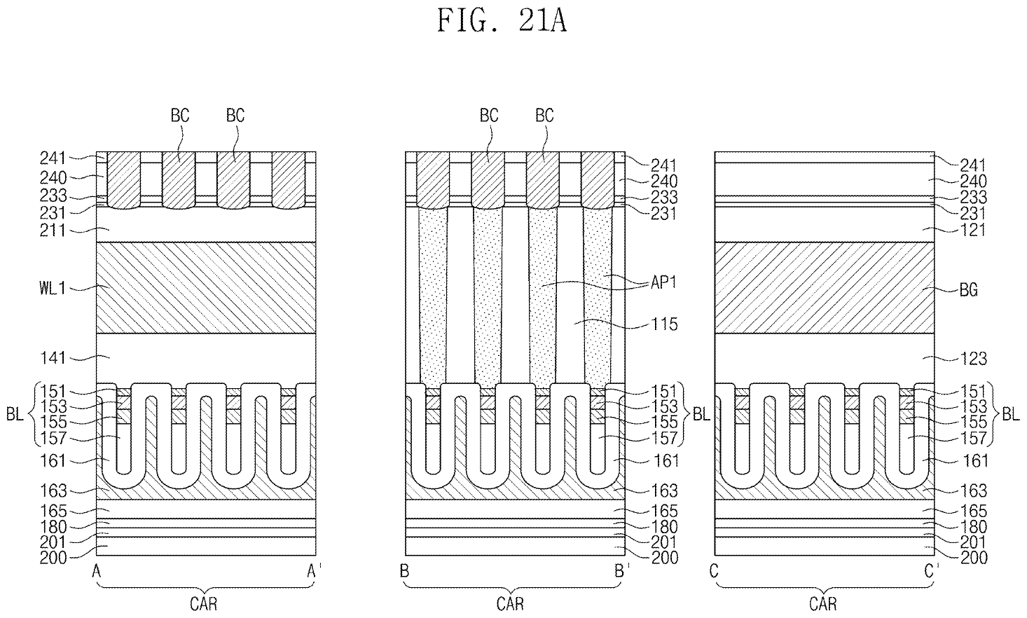

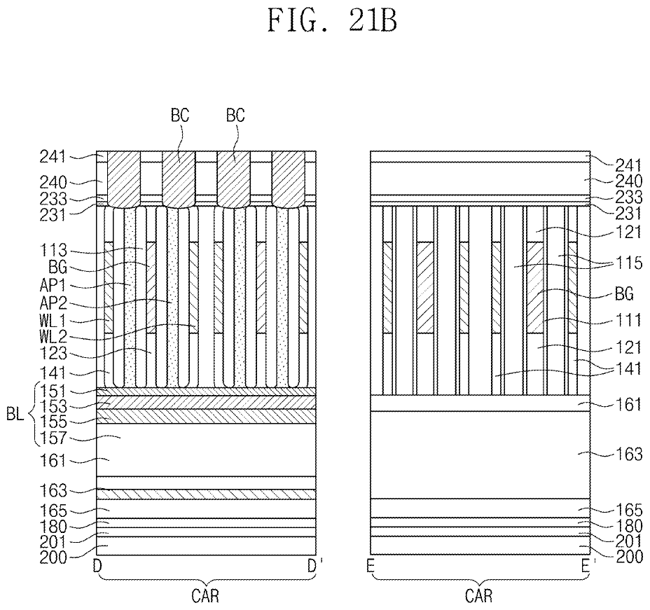

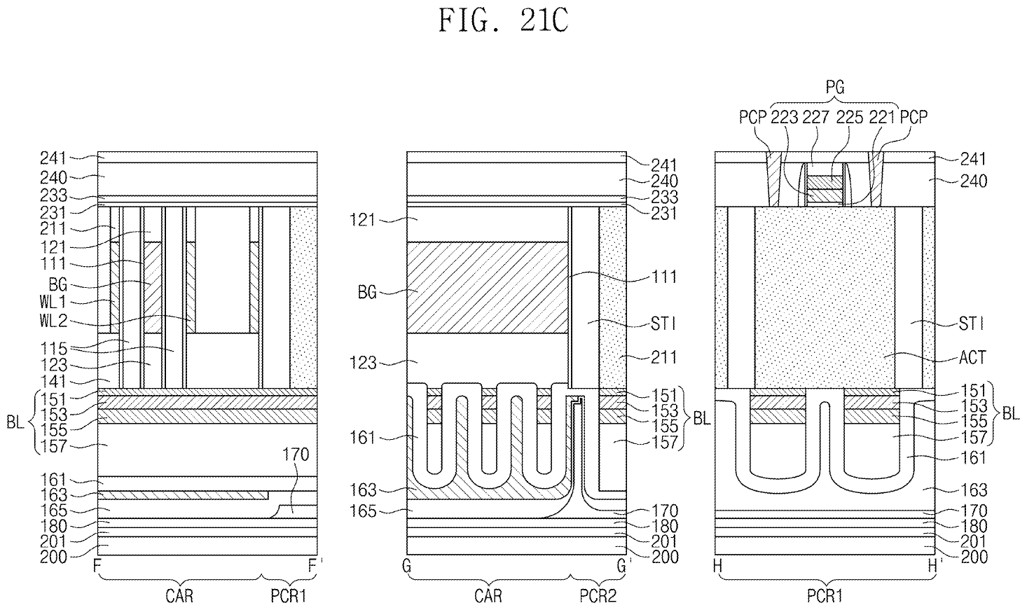

Referring to FIGS. 1, 21A, 21B, and 21C, the contact patterns BC may be formed in the cell array region CAR to penetrate the third etch stop layer 241, the interlayer insulating layer 240, and the second and first etch stop layers 233 and 231 and to be connected to the first and second active patterns AP1 and AP2.

The formation of the contact patterns BC may include patterning the third etch stop layer 241, the interlayer insulating layer 240, and the second and first etch stop layers 233 and 231 to form holes exposing the first and second active patterns AP1 and AP2, respectively, depositing a conductive layer to fill the holes, and planarizing the conductive layer to expose a top surface of the third etch stop layer 241.

After the formation of the contact patterns BC, the peripheral contact plugs PCP may be formed in the first and second peripheral circuit regions PCR1 and PCR2.

The formation of the peripheral contact plugs PCP may include patterning the third etch stop layer 241 and the interlayer insulating layer 240 to form contact holes and depositing a conductive material on the third etch stop layer 241 to fill the contact holes. The peripheral contact plugs PCP may penetrate the third etch stop layer 241 and the interlayer insulating layer 240 and may be connected to the peripheral transistor. For example, some of the peripheral contact plugs PCP may be connected to the source/drain regions of the peripheral transistors, and others of the peripheral contact plugs PCP may be connected to the peripheral gate electrodes PG.

Referring back to FIGS. 1, 2A, 2B, and 2C, the landing pads LP, which are respectively connected to the contact patterns BC, may be formed in the cell array region CAR.

The formation of the landing pads LP may include depositing a conductive layer on the third etch stop layer 241 and patterning the conductive layer using mask patterns.

When the landing pads LP are formed, peripheral interconnection lines PCL, which are connected to the peripheral contact plugs PCP, may be formed in the first and second peripheral circuit regions PCR1 and PCR2.

Before or after the formation of the landing pads LP, the fourth etch stop layer 243 may be formed on the third etch stop layer 241. The landing pads LP and the peripheral interconnection lines PCL may be formed in the third etch stop layer 241.

Next, the storage electrodes 251, which are respectively connected to the landing pads LP, may be formed. In an embodiment, the storage electrodes 251 may be formed of or include at least one of doped polysilicon, conductive metal nitride materials (e.g., titanium nitride and tantalum nitride), metallic materials (e.g., tungsten, titanium, and tantalum), conductive metal silicide materials, or conductive metal oxide materials.

Next, the capacitor dielectric layer 253 may be formed to conformally cover the storage electrodes 251. Thereafter, the plate electrode 255 may be formed on the capacitor dielectric layer 253.

After the formation of the data storage patterns DSP, the peripheral circuit insulating layer 260 may be formed to cover the first and second peripheral circuit regions PCR1 and PCR2, and the upper insulating layer 270 may be formed on the data storage patterns DSP and the peripheral circuit insulating layer 260.

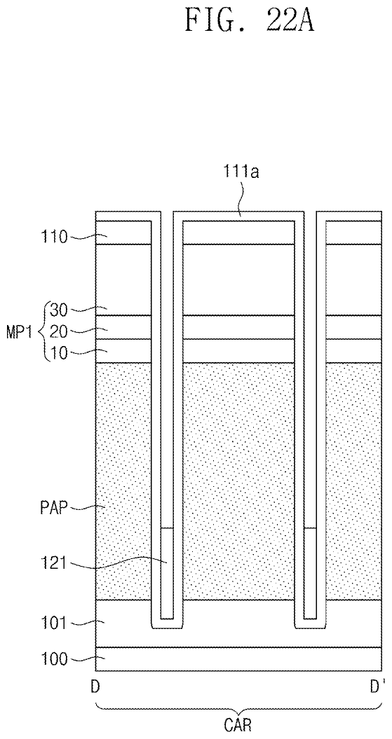

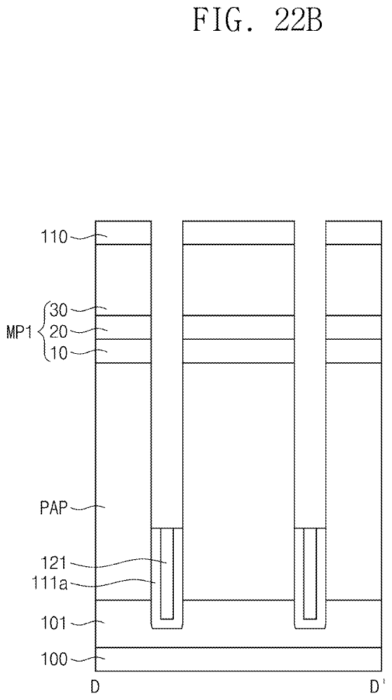

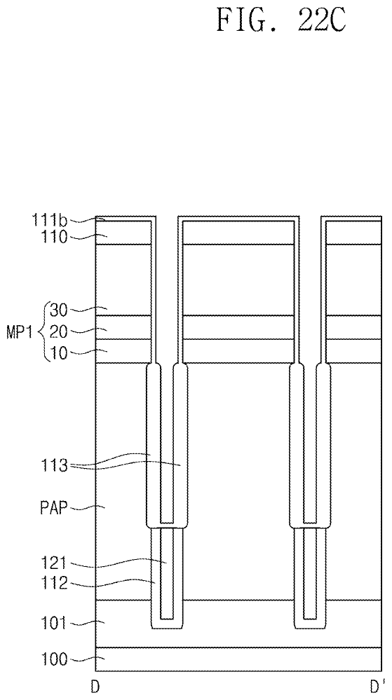

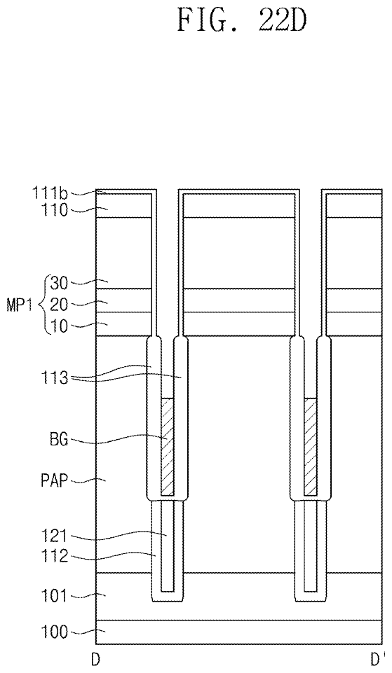

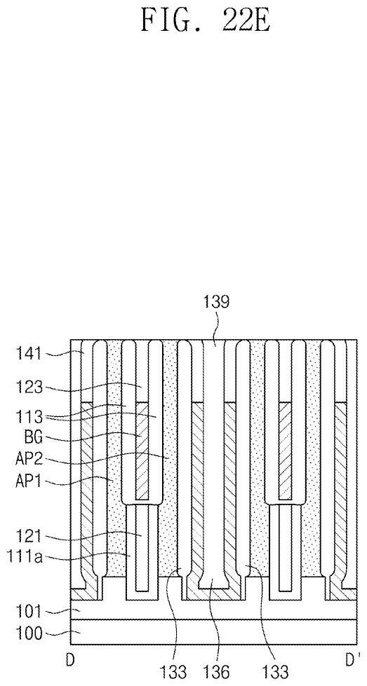

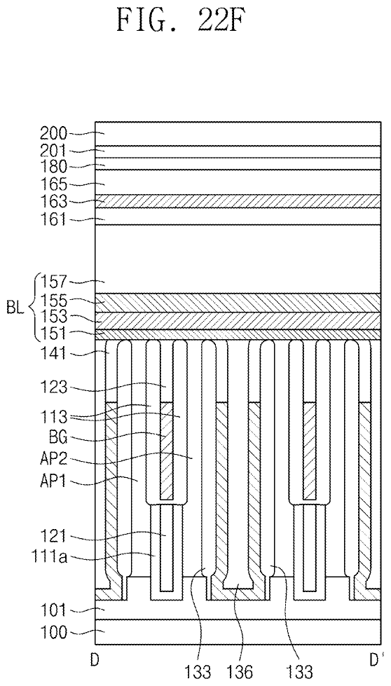

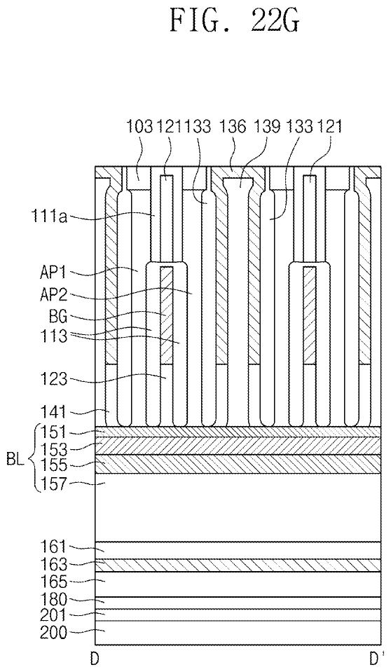

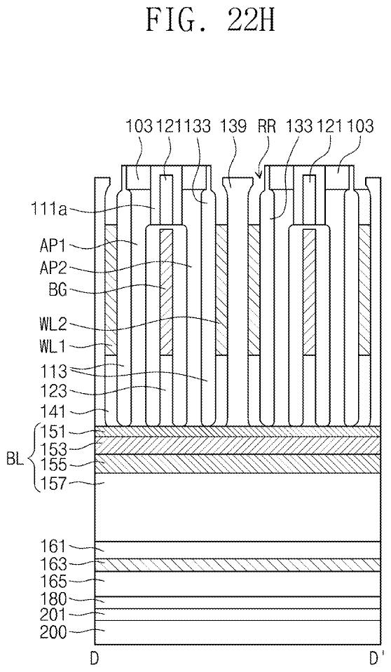

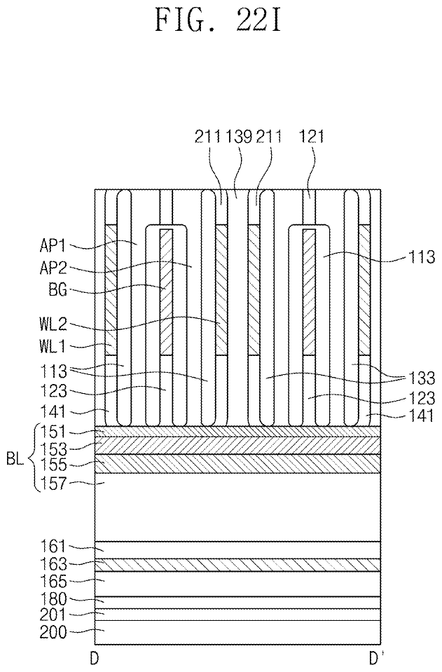

FIGS. 22A to 22I are sectional views, which are taken along the line D-D′ of FIG. 1 to illustrate a method of fabricating a semiconductor memory device according to an embodiment.

Referring to FIGS. 1 and 22A, the preliminary active patterns PAP may be formed on the buried insulating layer 101, as previously described with reference to FIGS. 6A, 6B, and 6C, and then, a first liner insulating layer 111a may be formed to conformally cover the second trenches.

The first liner insulating layer 111a may be formed by at least one of low-pressure chemical vapor deposition (LP-CVD), plasma-enhanced chemical vapor deposition (PE-CVD), and atomic layer deposition (ALD) techniques. Accordingly, the first liner insulating layer 111a may be formed to have a substantially uniform thickness on a top surface of the separation insulating layer 110, a side surface of the separation insulating layer 110 exposed by the second trench T2, and a top surface of the buried insulating layer 101 exposed by the second trench T2. In an embodiment, the first liner insulating layer 111a may be formed of silicon oxide.

Next, the first back-gate capping pattern 121 may be formed in the second trenches T2 with the first liner insulating layer 111a.

The first back-gate capping pattern 121 may be formed to fill the lower portion of the second trench T2, as described with reference to FIGS. 9A, 9B, and 9C.

A top surface of the first back-gate capping pattern 121 may be higher than the top surface of the buried insulating layer 101 and may be lower than the top surfaces of the preliminary active patterns PAP.

Referring to FIG. 22B, after the formation of the first back-gate capping pattern 121, an isotropic etching process may be performed on the first liner insulating layer 111a. Thus, the upper side surfaces of the first and second active patterns AP1 and AP2 may be exposed, and the top surface of the separation insulating layer 110 may be exposed.

Referring to FIG. 22C, a second liner insulating layer 111b may be formed to conformally cover inner surfaces of the second trenches T2 with the first back-gate capping pattern 121. The second liner insulating layer 111b may be formed to have a substantially uniform thickness on the top surface of the separation insulating layer 110, the side surface of the separation insulating layer 110 exposed by the second trenches T2, and the top surface of the first back-gate capping pattern 121 exposed by the second trench T2. In an embodiment, the second liner insulating layer 111b may be formed of silicon oxide.

In an embodiment, before the formation of the second liner insulating layer 111b, a thermal oxidation process may be performed to form the back-gate insulating layer 113 on the side surfaces of the preliminary active patterns PAP exposed by the second trenches T2, as described with reference to FIGS. 8A, 8B, and 8C.

Next, referring to FIG. 22D, the back-gate electrodes BG may be respectively formed in the second trenches T2 with the second liner insulating layer 111b. The back-gate electrodes BG may be formed by depositing a gate conductive layer to fill the second trenches T2 and isotropically etching a portion of the gate conductive layer, as described with reference to FIGS. 9A, 9B, and 9C. The first surfaces of the back-gate electrodes BG may be located at a level lower than the first surfaces of the preliminary active patterns PAP.

Referring to FIG. 22E, the second back-gate capping patterns 123 may be formed on the first surfaces of the back-gate electrodes BG, as described with reference to FIGS. 10A, 10B, and 10C.

Next, as previously described with reference to FIGS. 10A to 11C, the first and second active patterns AP1 and AP2 may be formed at both sides of the back-gate electrode BG. In the present embodiment, each of the first and second active patterns AP1 and AP2 may be formed such that a width on the first surface is different from a width on the second surface. As an example, in each of the first and second active patterns AP1 and AP2, the width may be larger on the second surface than on the first surface. Here, the first surface and the second surface may be opposite to each other in a direction perpendicular to the top surface of the first substrate 100.

After the formation of the first and second active patterns AP1 and AP2, the first and second gate insulating layers 131 and 133 may be formed, as described with reference to FIGS. 11A, 11B, and 11C, and the preliminary gate conductive patterns 136, the second separation insulating patterns 139, and the first gate capping patterns 141 may be sequentially formed, as described with reference to FIGS. 12A, 12B, and 12C.

Next, referring to FIG. 22F, the bit lines BL, which are extended in the first direction D1 may be formed, as described with reference to FIGS. 13A, 13B, and 13C. Next, the spacer insulating layer 161, the shielding conductive pattern 163, and the capping insulating layer 165 may be sequentially formed, as described with reference to FIGS. 14A, 14B, and 14C.

Next, the second substrate 200 may be bonded to the structure with the first substrate 100 using the first and second adhesive layers 180 and 201.

Referring to FIG. 22G, the first substrate 100 and a portion of the buried insulating layer 101 may be removed to expose the horizontal portions of the preliminary gate conductive patterns 136. The first liner insulating layer 111a may also be exposed, when the horizontal portions of the preliminary gate conductive patterns 136 are exposed.

Next, referring to FIG. 22H, as described with reference to FIGS. 17A, 17B, and 17C, the recess regions RR may be formed by etching the horizontal portions and portions of the vertical portions of the preliminary gate conductive patterns 136. As a result of the formation of the recess regions RR, the first and second word lines WL1 and WL2 may be formed to cross the side surfaces of the first and second active patterns AP1 and AP2.

Next, referring to FIG. 22I, the second gate capping patterns 211 may be formed in the recess regions RR. Here, the second gate capping patterns 211 may have a seam or void formed therein, as described above, and the seam in the second gate capping patterns 211 may be formed in an opposite direction to the seam in the first back-gate capping pattern 121.

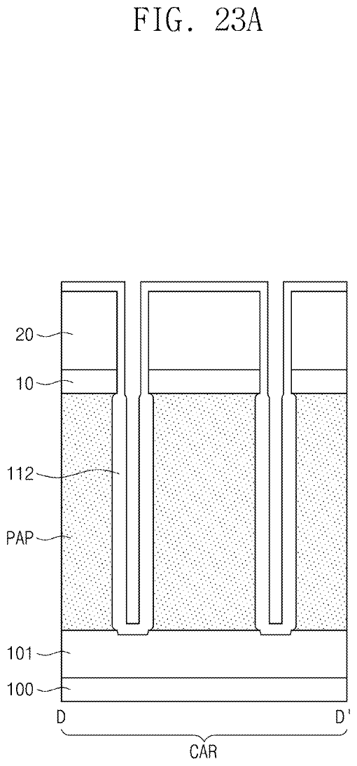

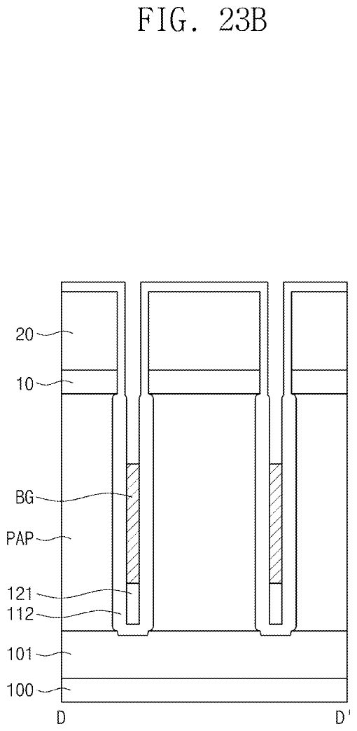

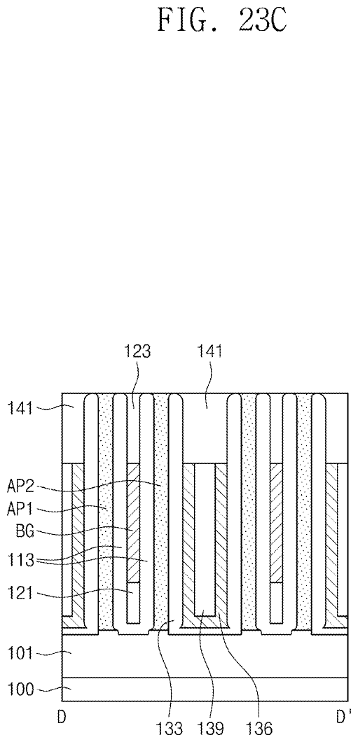

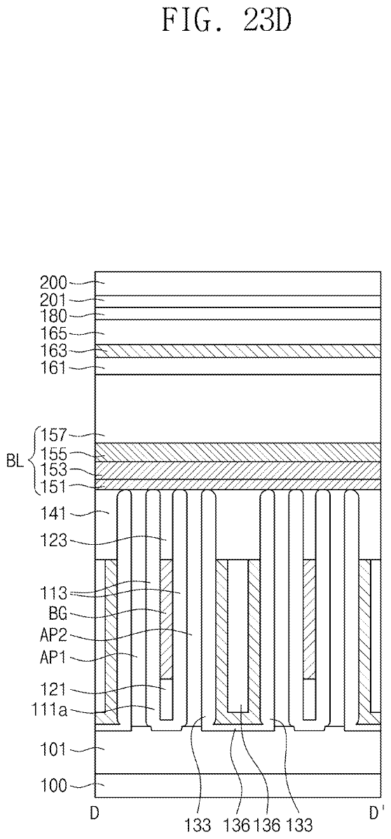

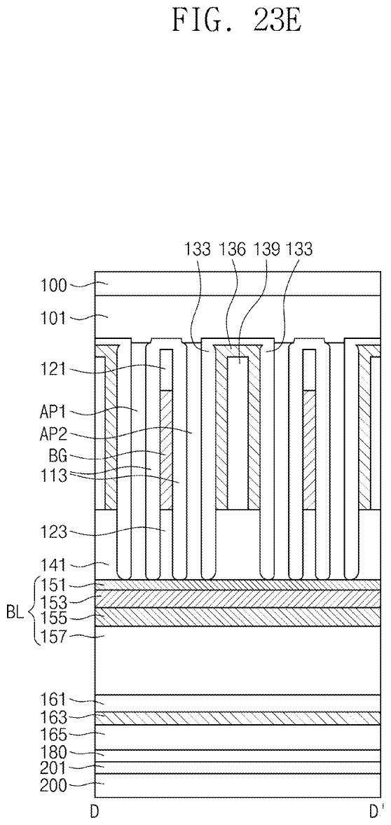

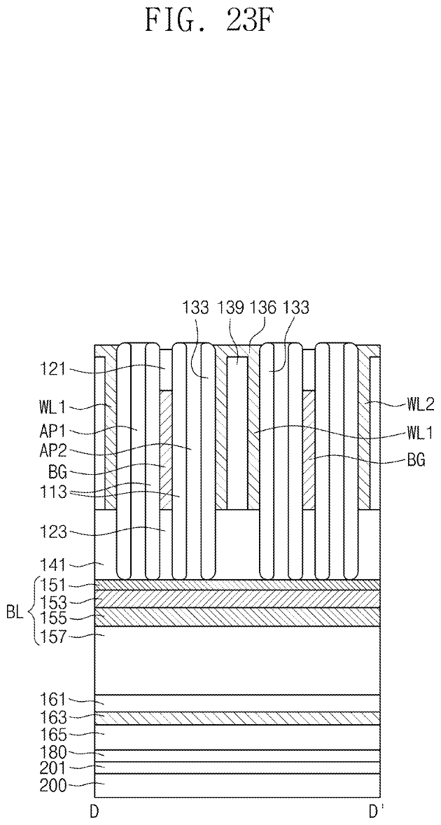

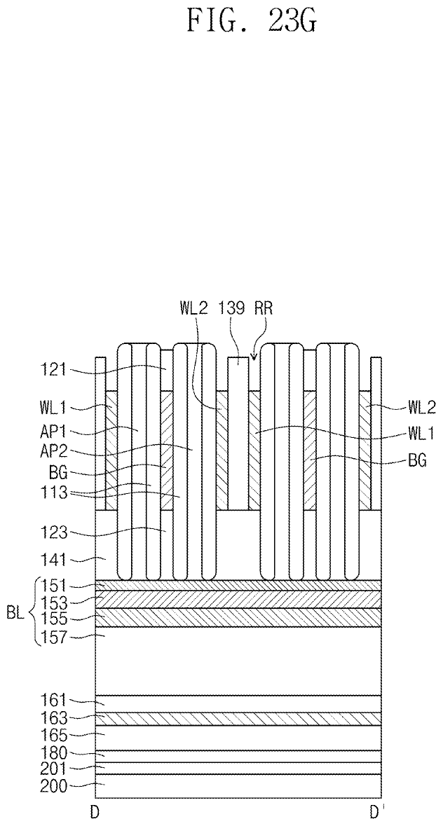

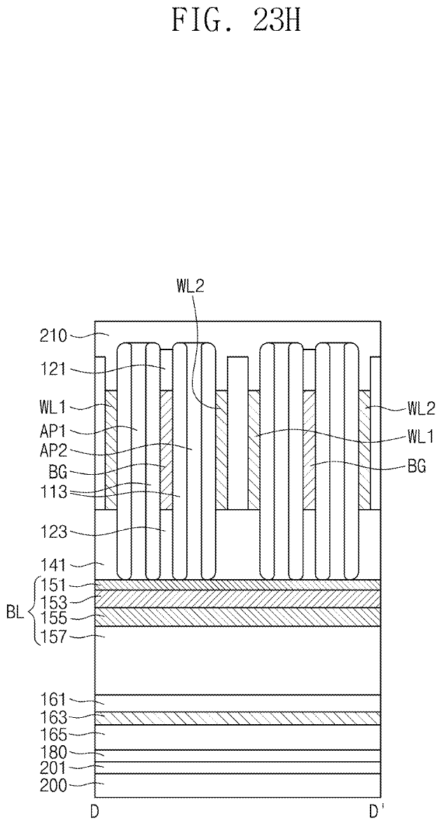

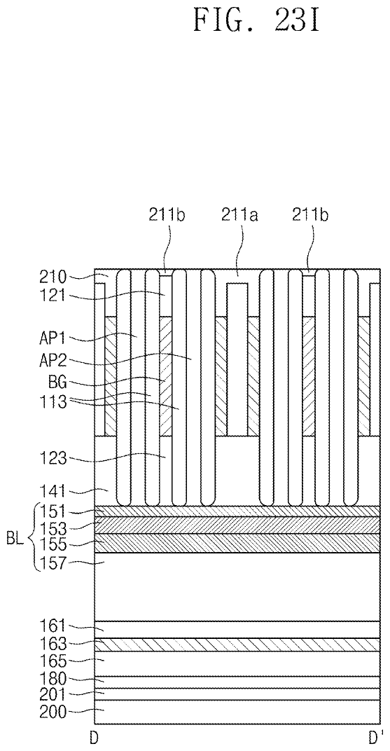

FIGS. 23A to 23I are sectional views, which are taken along the line D-D′ of FIG. 1 to illustrate a method of fabricating a semiconductor memory device according to an embodiment.

Referring to FIGS. 1 and 23A, the first and second trenches T1 and T2 previously described with reference to FIGS. 7A, 7B, and 7C may be formed using the first mask layer 10 and the second mask layer 20, which are sequentially stacked on the active layer, as a etch mask, and as a result, the preliminary active patterns PAP may be formed. Here, the first mask layer 10 may be formed of or include silicon oxide, and the second mask layer 20 may be formed of or include silicon nitride.

Next, a back-gate insulating layer 112 may be formed to cover a top surface of the second mask layer 20, side surfaces of the preliminary active patterns PAP exposed by the second trenches T2, and top surfaces of the buried insulating layer 101 exposed by the second trenches T2. Here, the back-gate insulating layer 112 may be deposited on inner surfaces of the second trenches and the top surface of the second mask layer 20 using a deposition process.

Referring to FIGS. 1 and 23B, the first back-gate capping pattern 121 and the back-gate electrode BG may be formed in the second trenches T2 with the back-gate insulating layer 112.

Referring to FIG. 23C, as described above, the second back-gate capping pattern 123 may be formed on the back-gate electrode BG and the first and second active patterns AP1 and AP2 may be formed at both sides of the back-gate electrode BG.

In addition, the first and second gate insulating layers 131 and 133 may be formed, as described with reference to FIGS. 11A, 11B, and 11C, and the preliminary gate conductive patterns 136, the second separation insulating patterns 139. The first gate capping patterns 141 may be sequentially formed, as described with reference to FIGS. 12A, 12B, and 12C. Here, the first gate capping patterns 141 may cover the preliminary gate conductive patterns 136 and the second separation insulating patterns 139.

The second back-gate capping pattern 123 and the first gate capping patterns 141 may have top surfaces that are substantially coplanar with the top or first surfaces of the first and second active patterns AP1 and AP2.

Next, referring to FIG. 23D, the bit lines BL, which extend in the first direction D1, may be formed, as described with reference to FIGS. 13A, 13B, and 13C. Next, the spacer insulating layer 161, the shielding conductive pattern 163, and the capping insulating layer 165 may be sequentially formed, as described with reference to FIGS. 14A, 14B, and 14C.

Next, the second substrate 200 may be bonded to the structure with the first substrate 100 using the first and second adhesive layers 180 and 201.

Next, referring to FIG. 23E, the first substrate 100 and the portion of the buried insulating layer 101 may be removed to expose the horizontal portions of the preliminary gate conductive patterns 136. When the horizontal portions of the preliminary gate conductive patterns 136 are exposed, the top surfaces of the first and second active patterns AP1 and AP2 and the top surfaces of the first back-gate capping pattern 121 may also be exposed. Here, the top surfaces of the first back-gate capping pattern 121 may be located at a level lower than the top surfaces of the first and second active patterns AP1 and AP2. Referring to FIG. 23F, the recess regions RR may be formed by etching the horizontal portions and portions of the vertical portions of the preliminary gate conductive patterns 136, as described with reference to FIGS. 17A, 17B, and 17C. After the formation of the recess regions RR, the second separation insulating patterns 139 may have top surfaces which are located at a level lower than the top surfaces of the first and second active patterns AP1 and AP2.

Referring to FIG. 23G, the second gate capping layer 210 may be formed to fill the recess regions RR. The second gate capping layer 210 may cover the second separation insulating patterns 139. As described above, when the second gate capping layer 210 is deposited, a discontinuous interface (e.g., a seam or void) may be formed in the second gate capping layer 210.

Referring to FIG. 23H, after the formation of the second gate capping layer 210, a planarization process may be performed on the second gate capping layer 210, until the top surfaces of the first and second active patterns AP1 and AP2 are exposed to the outside. Thus, the second gate capping patterns 211a may be formed on the first and second word lines WL1 and WL2.

Next, referring to FIG. 23I, the second gate capping patterns 211a may be formed in the recess regions RR. Here, the second gate capping patterns 211a may have a seam or void formed therein, as described above, and the seam in the second gate capping patterns 211a may be formed in an opposite direction to the seam in the first back-gate capping pattern 121.

During the formation of the second gate capping patterns 211a, the dummy capping pattern 211b may be disposed on the first back-gate capping pattern 121. The second gate capping patterns 211a and the dummy capping pattern 211b may be substantially coplanar with the top surfaces of the first and second active patterns AP1 and AP2.

According to an embodiment, in the semiconductor memory device including the vertical channel transistors, the active patterns may be formed of a single-crystalline semiconductor material, and in this case, the leakage current property of the vertical channel transistor may be improved.

According to an embodiment, the back-gate electrode may be provided to increase the threshold voltage of the vertical channel transistor, and thus, it may be possible to suppress a reduction of the threshold voltage of the vertical channel transistor, which could occur when the vertical channel transistor is scaled down, and thereby to prevent the leakage current property of the vertical channel transistor from being deteriorated.

According to an embodiment, a method of bonding the first substrate to the second substrate may be used to fabricate the semiconductor memory device including the vertical channel transistors. Here, the first back-gate capping pattern, which electrically separates the contact patterns from the back-gate electrode, may be formed before the process of bonding the first substrate to the second substrate. In this case, it may be possible to secure a process margin in a process of forming the second gate capping patterns, which are used to electrically separate the first and second word lines from the contact patterns after the bonding process.

By way of summation and review, embodiments provide a semiconductor memory device, and in particular, a semiconductor memory device with improved electrical characteristics and an increased integration density

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor memory device, comprising:
a substrate;
a bit line disposed on the substrate and extending in a first direction;
a first word line and a second word line extending in a second direction to cross the bit line;
a back-gate electrode disposed between the first word line and the second word line and extending in the second direction;
a first active pattern disposed between the first word line and the back-gate electrode and connected to the bit line;
a second active pattern disposed between the second word line and the back-gate electrode and connected to the bit line;
contact patterns coupled to the first and second active patterns, respectively;
a first back-gate capping pattern between the contact patterns and a top surface of the back-gate electrode; and
first gate capping patterns between the contact patterns and top surfaces of the first and second word lines,
wherein:
the first back-gate capping pattern has a first seam that is formed therein and that extends in the second direction,
each of the first gate capping patterns has a second seam that is formed therein and extends in the second direction, and
the first seam and the second seam are located at different vertical levels.

2. The semiconductor memory device as claimed in claim 1, wherein the first seam of the first back-gate capping pattern is vertically spaced apart from the contact patterns and is adjacent to the top surface of the back-gate electrode.

3. The semiconductor memory device as claimed in claim 1, wherein the second seams of the first gate capping patterns are vertically spaced apart from the top surfaces of the first and second word lines and are adjacent to the contact patterns.

4. The semiconductor memory device as claimed in claim 1, wherein the top surfaces of the first and second word lines are located at substantially the same level as the top surface of the back-gate electrode.

5. The semiconductor memory device as claimed in claim 1, wherein the top surfaces of the first and second word lines are located at a level different from the top surface of the back-gate electrode.

6. The semiconductor memory device as claimed in claim 1, wherein the top surface of the back-gate electrode is in contact with the first back-gate capping pattern and has a rounded shape.

7. The semiconductor memory device as claimed in claim 1, further comprising liner insulating patterns disposed between the first back-gate capping pattern and the first and second active patterns.

8. The semiconductor memory device as claimed in claim 1, further comprising:
a peripheral active pattern provided on a peripheral circuit region of the substrate, the peripheral active pattern having a first surface and a second surface, which are opposite to each other; and
a peripheral transistor integrated on the first surface of the peripheral active pattern,
wherein;
the first and second active patterns have first surfaces that are adjacent to the contact patterns, and second surfaces that are adjacent to the bit lines, and
the second surface of the peripheral active pattern is located at substantially the same level as the second surfaces of the first and second active patterns.

9. A semiconductor memory device, comprising:
a substrate;
a bit line provided on the substrate and extending in a first direction;
first and second active patterns alternately disposed in the first direction on the bit line;
a back-gate electrode disposed between adjacent ones of the first and second active patterns and extending in a second direction to cross the bit line;
first word lines disposed adjacent to first side surfaces of the first active patterns respectively and extending in the second direction;
second word lines disposed adjacent to second side surfaces of the second active patterns respectively and extending in the second direction;
contact patterns connected to the first and second active patterns, respectively;
a first back-gate capping pattern between the contact patterns and the back-gate electrode;
first gate capping patterns between the contact patterns and the first word lines and second word lines;
a second back-gate capping pattern between the bit line and the back-gate electrode; and
second gate capping patterns between the bit line and the first word lines and second word lines,
wherein:
the first back-gate capping pattern has a first seam that is formed therein and is adjacent to the back-gate electrode,
each of the first gate capping patterns has a second seam that is formed therein and is adjacent to the contact patterns,
the first seam of the first back-gate capping pattern is vertically spaced apart from the contact patterns, and
the second seams of the first gate capping patterns are vertically spaced apart from top surfaces of the first word lines and second word lines.

10. The semiconductor memory device as claimed in claim 9, further comprising first gate insulating patterns, which are respectively disposed between the first and second active patterns and the back-gate electrode, and wherein:
the first back-gate capping pattern is disposed between the first gate insulating patterns.

11. The semiconductor memory device as claimed in claim 9, further comprising:
second gate insulating patterns, which are respectively disposed between the first and second active patterns and the first word lines and second word lines; and
a separation insulating pattern, which is disposed between the first word lines and second word lines adjacent to each other in the first direction,
wherein the first gate capping patterns are respectively disposed between the separation insulating pattern and the second gate insulating patterns.

12. The semiconductor memory device as claimed in claim 9, further comprising a separation insulating pattern, which is disposed between the first word lines and second word lines adjacent to each other in the first direction,
wherein a top surface of the first word lines and a top surface of the second word lines are located at a level different from a top surface of the separation insulating pattern.

13. The semiconductor memory device as claimed in claim 9, wherein:
the back-gate electrode has a top surface that is in contact with the first back-gate capping pattern,
the first word lines and second word lines have top surfaces that are in contact with the first gate capping patterns, and
the top surfaces of the first and second word lines are located at a level different from the top surface of the back-gate electrode.

14. The semiconductor memory device as claimed in claim 9, wherein the first seam and the second seam extend in the second direction.

15. The semiconductor memory device as claimed in claim 9, wherein, when measured in the first direction, a width of each of the first and second active patterns is smaller than a width of each of the contact patterns.

16. The semiconductor memory device as claimed in claim 9, further comprising data storage patterns disposed on the contact patterns.

17. A semiconductor memory device, comprising:
a substrate;
bit lines disposed on the substrate and extending in a first direction;
a shielding conductive pattern including line portions, which are disposed between adjacent ones of the bit lines and extend in the first direction;
first and second active patterns alternately disposed in the first direction, on each of the bit lines;
contact patterns coupled to the first and second active patterns, respectively;
back-gate electrodes, which are respectively disposed between adjacent ones of the first and second active patterns and extend in a second direction to cross the bit lines;
first word lines disposed adjacent to the first active patterns respectively and extending in the second direction;
second word lines disposed adjacent to the second active patterns respectively and extending in the second direction;
a first back-gate capping pattern between the contact patterns and the back-gate electrode;
a first gate capping patterns between the contact patterns and the first word lines and second word lines;
a second back-gate capping pattern between the bit lines and the back-gate electrode;
second gate capping patterns between the bit lines and the first word lines and second word lines;
contact patterns coupled to the first and second active patterns, respectively; and
data storage patterns coupled to the contact patterns, respectively,
wherein:
the first back-gate capping pattern has a first seam that is formed therein and extends in the second direction,
each of the first gate capping patterns has a second seam that is formed therein and extends in the second direction,
the first seam is adjacent to a top surface of the back-gate electrode, and
the second seams are adjacent to the contact patterns.

18. The semiconductor memory device as claimed in claim 17, further comprising:
a shielding conductive pattern including line portions that are respectively disposed between adjacent ones of the bit lines and extend in the first direction; and
a spacer insulating layer disposed between the shielding conductive pattern and the bit lines.

19. The semiconductor memory device as claimed in claim 17, further comprising:
gate insulating patterns that are respectively disposed between the first and second active patterns and the first word lines and second word lines; and
a separation insulating pattern that is disposed between the first word lines and second word lines facing each other,
wherein the first gate capping patterns and the first back-gate capping pattern include an insulating material different from the separation insulating pattern.

20. The semiconductor memory device as claimed in claim 17, wherein, when measured in the first direction, a width of each of the first and second active patterns is less than a width of each of the contact patterns.
